(19) United States
(12) Patent Application Publication
(10) Pub. No.: US 2004/0072096 A1
(43) Pub. Date: Apr. 15, 2004

(54) Micropattern forming material and fine structure forming method

(75) Inventors: Mamoru Terai, Tokyo (JP); Toshiyuki Toyoshima, Tokyo (JP); Takeo Ishibashi, Tokyo (JP); Shinji Tarutani, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/641,392

(22) Filed: Aug. 15, 2003

(30) Foreign Application Priority Data
Aug. 30, 2002 (JP) 2002-253923

(51) Int. Cl. G03F 7/004

(52) U.S. Cl. 430/270.1; 430/281.1; 430/325; 430/296

(57) ABSTRACT

A micropattern forming material comprising a water-soluble component, water and/or an organic solvent miscible with water is used. The water-soluble component is made of at least one selected from the group water-soluble monomers, water-soluble oligomers, copolymers of water-soluble monomers and salts thereof, having a functional group reactable with a carboxyl group. The micropattern forming material is formed on a resist pattern 4 capable of supplying an acid, and a film 6 insoluble in water or an alkali is formed through crosslinking reaction of the water-soluble component at a portion in contact with the resist pattern 4 by the action of the acid from the resist pattern.

### BACKGROUND OF THE INVENTION

1. Field of the Invention

The present invention relates to a micropattern forming material and a method for forming a fine structure.

2. Background Art

In recent years, as the degree of integration of semiconductor devices increases, the sizes of individual elements become increasingly smaller, along with smaller widths of wirings, gates and the like constituting individual elements. In general, a micropattern is formed by forming a desired resist pattern according to a photolithographic technique and etching different types of underlying thin films through the resist pattern as a mask. In this sense, the photolithographic technique is very important for the formation of the micropattern.

The photolithographic technique includes the steps of coating of a resist, positioning of a mask, light exposure and development. In this connection, however, with recent cutting-edge devices, the pattern dimension is now coming close in on the limit of resolution by light exposure, and thus it is required that an exposure technique of a higher degree of resolution be developed.

For conventional exposure techniques, methods of forming a fine resist pattern are known wherein mutual diffusion of resin components for a first resist and a second resist are used (e.g. see Japanese patent Laid-open No. Hei 6-250379, and Japanese Patent Laid-open No. Hei 7-134422).

On the other hand, we have disclosed a method of forming a micropattern by forming a layer made of a micropattern forming material on a resist pattern (e.g. see Japanese Patent Laid-open No. Hei 10-73927). In this method, the quantity of reaction between the micropattern forming material and the resist is controlled by controlling a mixing ratio between a water-soluble resin and a water-soluble crosslinking agent contained in the micropattern forming material.

With the method of forming a fine resist pattern by using mutual diffusion of the first resist and the second resist, the second resist is made of a photoresist material soluble in an organic solvent, which is able to dissolve the first resist, with the attendant problem that the first resist pattern is deformed.

With the method of forming a micropattern by forming the layer made of a micropattern-forming material on a resist pattern, the reactivity of the micropattern-forming material with an acrylic resist is so low that a problem is involved in that the film-forming properties of the micropattern-forming material on the acrylic resin lower, with a difficulty in forming a micropattern having a desired size. For instance, where an ArF resist is used as an underlying layer, such a problem is presented that the layer made of the micropattern-forming material is formed in a thickness smaller than as desired.

A further problem is that when micropatterns are formed on a resist pattern, bridging may take place wherein the patterns are mutually, partially combined together.

### SUMMARY OF THE INVENTION

The invention is made to solve the above problems, and its object is to provide a micropattern forming material which ensures the formation of a micropattern beyond the limit of an exposure wavelength in a photolithographic technique, a micropattern forming method using the material, and a method for manufacturing a semiconductor device.

Another object of the invention is to provide a micropattern forming material which is unable to dissolve an underlying resist, a method for forming a micropattern using the material, and a method for manufacturing a semiconductor device.

Another object of the invention is to provide a micropattern forming material capable of conveniently forming a micropattern on an acrylic resist, a method for forming a micropattern using the material, and a method for manufacturing a semiconductor device.

Another object of the invention is to provide a micropattern forming a material capable of reducing defects such as bridging, a method for forming a micropattern using the material, and a method for manufacturing a semiconductor device.

Other objects and advantages of the invention will become apparent from the following description.

According to one aspect of the present invention, a micropattern forming material comprises a water-soluble component which is crosslinkable in the presence of an acid, and water and/or an organic solvent miscible with water. The micropattern forming material is coated on a resist pattern capable of supplying the acid. The water-soluble component consists of at least one selected from the group comprising water-soluble monomers, water-soluble oligomers, copolymers of water-soluble monomers and salts thereof, having a functional group reactable with a carboxyl group. And the water-soluble component is crosslinked at a portion in contact with the resist pattern to form a water or alkali-insoluble film.

According to another aspect of the present invention, in a method for forming a micropattern, a resist pattern capable of supplying an acid is formed on a support or a thin film formed on a support. A micropattern forming material is coated onto the resist pattern to form a micropattern forming film. The acid from the resist pattern is supplied to cause a crosslinking reaction at a portion of the micropattern forming film in contact with the resist pattern to form a water or alkali-insoluble film. A water or alkali-soluble portion of the micropattern forming film is removed. And, the micropattern forming material comprises a water-soluble component consisting of at least one selected from the group comprising water-soluble monomers, water-soluble oligomers, copolymers of water-soluble monomers and salts thereof, having a functional group reactable with a carboxyl group, and water and/or an organic solvent miscible with water.

Other and further objects, features and advantages of the invention will appear more fully from the following description.

### BRIEF DESCRIPTION OF THE DRAWINGS

FIG. 1A shows a mask pattern of fine holes.

FIG. 1B shows a mask pattern of fine spaces.

FIG. 1C shows a mask pattern of an island pattern.

FIGS. 2A to 2F show a method of manufacturing a semiconductor device according to the first embodiment.

FIG. 3 is cross section of a fine pattern according to the present invention.

FIGS. 4A to 4G show a method of manufacturing a semiconductor device according to the second embodiment.

FIGS. 5A to 5G show a method of manufacturing a semiconductor device according to the third embodiment.

FIGS. 6A to 6G show a method of manufacturing a semiconductor device according to the fourth embodiment.

FIGS. 7A to 7F show a method of manufacturing a semiconductor device according to the fifth embodiment.

FIGS. 8A to 8G show a method of manufacturing a semiconductor device according to the fifth embodiment.

FIG. 9 shows a resist pattern and an isolation width thereof according to the examples 1 to 3.

FIG. 10 shows a resist pattern and an isolation width thereof according to the example 4.

FIG. 11 shows a resist pattern and an isolation width thereof according to the example 5.

FIG. 12 shows a resist pattern and an isolation width thereof according to the example 6.

FIG. 13 shows a fine pattern according to the examples 17 to 19 and 23 to 27.

FIG. 14 shows a fine pattern according to the examples 20 to 23.

FIG. 15 shows a resist pattern according to the example 28.

FIG. 16 shows a fine pattern according to the example 28.

### DETAILED DESCRIPTION OF THE PREFERRED EMBODIMENTS

The preferred embodiments of the invention are described in detail with reference to the accompanying drawings.

### First Embodiment

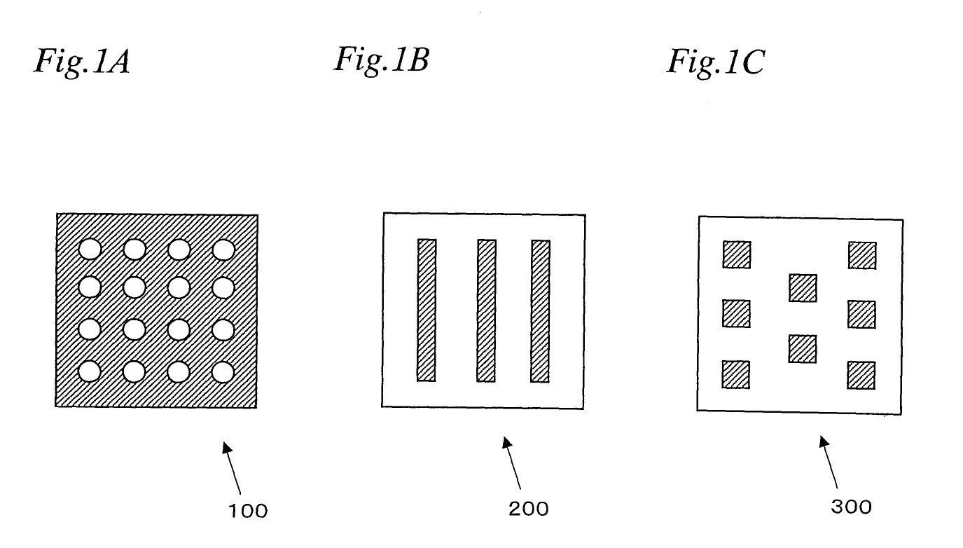

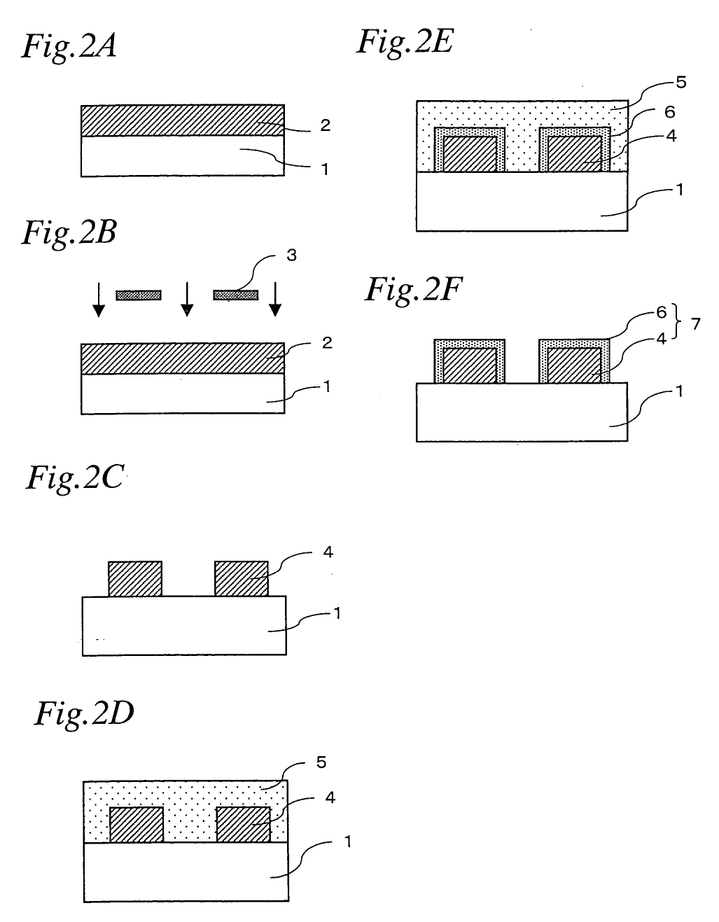

FIGS. 1A to 1C show an instance of a mask pattern for forming finely isolated resist patterns, to which the invention is directed. FIG. 1A shows a mask pattern 100 of fine holes, FIG. 1B shows a mask pattern 200 of fine spaces, and FIG. 1C shows an island pattern 300. In the figures, a shaded portion indicates a portion at which the resist is formed, for example, FIGS. 2A to 2F are process charts showing an instance of a method of manufacturing a semiconductor device according to this embodiment.

As shown in FIG. 2A, a resist composition is coated onto a semiconductor substrate 1 to form a resin film 2. For instance, a resist composition is coated onto a semiconductor substrate by a spin coating method or the like in a thickness of 0.7 μm to 1.0 μm.

In this embodiment, the resist composition used is one which is able to generate an acidic component inside the resist by application of heat. The resist composition includes a positive-type resist made of an acrylic resin or a novolac resin and a naphthoquinone azide photosensitizer, and a chemically amplified resist capable of generating an acid by application of heat. The resist composition may be either a positive-type resist or a negative-type resist.

Next, the solvent present in the resist film 2 is evaporated by a pre-baking treatment. The pre-baking treatment is carried out, for example, by thermal treatment using a hot plate at 70 to 110° C. for about 1 minute. Thereafter, as shown in FIG. 2B, the resist film 2 is exposed to light through a mask 3 containing such a pattern as shown in FIGS. 1A to 1C. The light source used for the exposure may be one which corresponds to a sensitivity wavelength of the resist film 2. Using such a light source, the resist film 2 is irradiated, for example, with a g-line spectrum of light, an i-line spectrum of light, deep UV light, a KrF excimer laser beam (248 nm), an ArF excimer laser beam (193 nm) and EB (electron beam), or an X ray.

After exposure of the resist film, PEB treatment (post-exposure baking treatment) is carried out, if necessary. This leads to an improved resolution of the resist film. The PEB treatment is performed, for example, by thermal treatment at 50 to 130° C.

Next, developing treatment is carried out by use of an appropriate liquid developer for patterning of the resist film. If the resist composition used is of the positive type, such a resist pattern 4 as shown in FIG. 2C is obtained. For a liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60 to 120° C. for about 60 seconds.

As shown in FIG. 2D, a micropattern forming material according to the invention is coated onto the resist pattern 4 to form a micropattern forming film 5. The manner of coating the micropattern forming material is not critical so far as uniform coating on the resist pattern 4 is ensured. For instance, a spraying method, a spin coating method or the like may be used for the coating. Alternatively, the micropattern forming film 5 may be formed on the resist pattern 4 by dipping the semiconductor device having a structure shown in FIG. 2C in the micropattern forming material.

The micropattern forming material of the invention has a feature in that it undergoes a crosslinking reaction in the presence of an acid and is insolubilized in a liquid developer. The formulation of the micropattern forming material is described in detail below.

The micropattern forming material according to the invention is characterized by comprising at least one water-soluble component capable of crosslinkage in the presence of an acid, and water and/or an organic solvent miscible with water. More specifically, either of water, an organic solvent miscible with water or a mixed solvent of water and an organic solvent miscible with water is used for the solvent, so that the underlying resist pattern is not dissolved.

The crosslinkable water-soluble component may be either of a polymer, a monomer or an oligomer. In the practice of the invention, a monomer, an oligomer or a polymer of a low degree of polymerization is preferred. Especially, it is more preferred to use a monomer, an oligomer polymerizing the monomer in number of 2 to 240, or an oligomer having an average molecular weight of 10,000 or below.

In the manufacturing process of a semiconductor device, a micro-fabrication technique of 100 nm or below may be required in some case. Where a polymer having an average molecular weight over 10,000 is used as a micropattern forming material, the molecular size reaches several tens of nm or over, which is considered to arrive at one-tenth of a processing size. Thus, this may bring about failures such as the lowering in control of a pattern size and the inaccuracy of a pattern shape. In the practice of the invention where a low molecular weight material such as a monomer or an oligomer is used as a water-soluble component, the size of the molecule constituting the micropattern forming material is made smaller than in conventional methods. Accordingly, it becomes possible to readily form a micropattern of 100 nm or below.

The water-soluble polymers used in the invention include those compounds shown in Formula 1 below.

### Chemical Formula 1

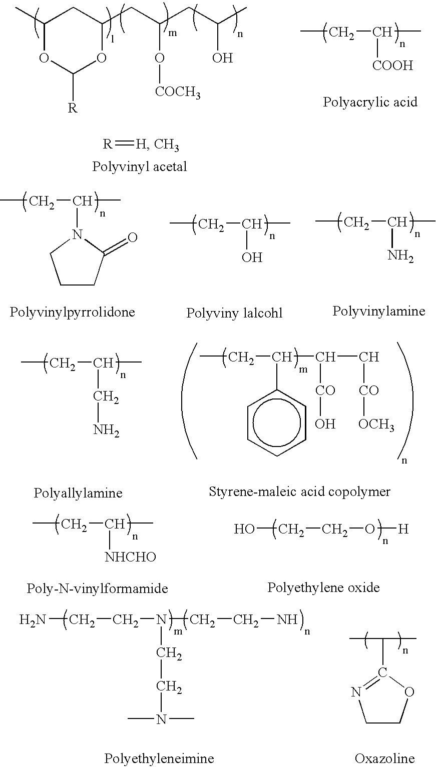

The water-soluble monomers used in the invention include sulfonate-containing monomers shown in Formula 2, carboxyl group-containing monomers shown in Formula 3, hydroxyl group-containing monomers shown in Formula 4, amido group-containing monomers shown in Formula 5, amino group-containing monomers shown in Formula 6, ether group-containing monomers shown in Formula 7, pyrrolidone derivatives shown in Formula 8, ethyleneimine derivatives shown in Formula 9, urea derivatives shown in Formula 10, melamine derivatives shown in Formula 11, glycoluril shown in Formula 12, and benzoguanamine shown in Formula 13. Additionally, diallylglycinonitrile group-containing monomers may also be used. Moreover, oligomers made of the monomers shown in Formulae 2 to 13 can be preferably used in the invention.

### Chemical Formula 2

### Sulfonate-Containing Monomers

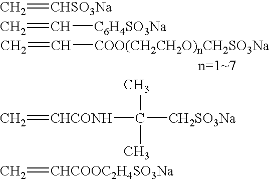

### Chemical Formula 3

### Carboxyl Group-Containing Monomers

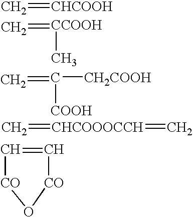

### Chemical Formula 4

### Hydroxyl Group-Containing Monomers

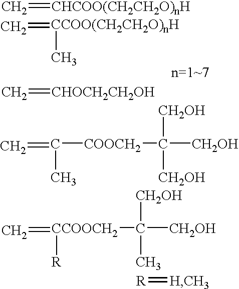

### Chemical Formula 5

### Amido Group-Containing Monomers

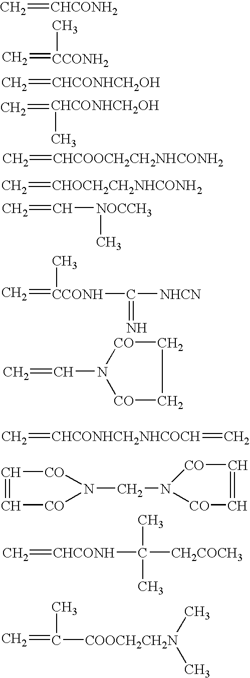

### Chemical Formula 6

### Amino Group-Containing Group

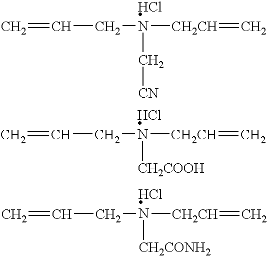

### Chemical Formula 7

### Ether Group-Containing Moomers

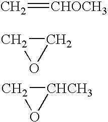

### Chemical Formula 8

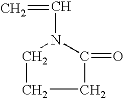

### Pyrrolidone Derivative

### Chemical Formula 9

### Ethyleneimine Derivatives

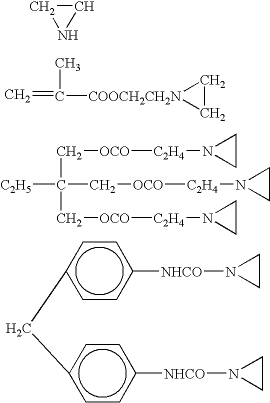

### Chemical Formula 10

### Urea Derivatives

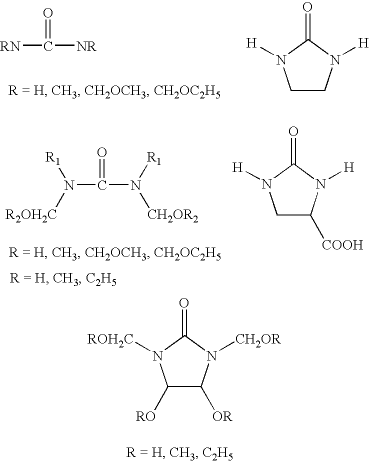

### Chemical Formula 11

### Melamine Derivatives

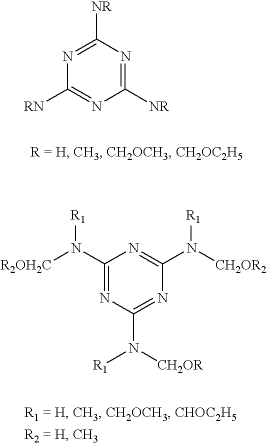

### Chemical Formula 12

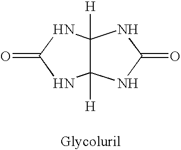

### Chemical Formula 13

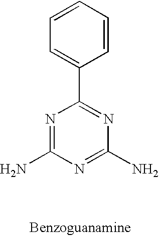

The micropattern forming materials of the invention can well react not only with a hydroxyl group (—OH), but also with a carboxyl group (—COOH). More specifically, if an acrylic resist is used for an underlying layer, a crosslinking reaction satisfactorily takes place at the interface between the micropattern forming film and the resist film. Accordingly, it becomes possible to form a film of a micropattern forming material on an acrylic resist in a satisfactory manner thereby forming a desired micropattern.

The crosslinkable, water-soluble component may consist of only one component, or may be made of a mixture of two or more components. In the embodiment of the invention, it is preferred to use a mixture of two or more types of ethyleneimine oligomers having different average molecular weights at appropriate ratios. In this case, the average molecular weight should preferably be within a range of 250 to 10,000. On the other hand, where only one type of ethyleneimine oligomer is used, the average molecular weight should preferably be within a range of 250 to 1,800.

Other instances of mixtures used for the crosslinkable, water-soluble component in the invention include a mixture of an allylamine oligomer and an ethyleneimine oligomer. It will be noted that where a mixture is used, the mixing ratio of the respective components should be determined depending on the type of resist composition used and the reaction conditions and is not critical.

For the crosslinkable, water-soluble component, a copolymer of two or more types of crosslinkable, water-soluble monomers may be used. Moreover, for the purpose of improving solubility in water, the above-mentioned polymers, monomers, oligomers or copolymers may be converted to and used as salts such as sodium salts or hydrochlorides.

The crosslinkable, water-soluble component may be dissolved in water (pure water) or may be dissolved in a mixed solvent of water and an organic solvent. The organic solvent mixed with water is not critical in type so far as it is miscible with water, and is mixed within a range of amount not permitting a resist pattern to be dissolved therein while taking into account the solubility of a resin used for the micropattern forming material. For instance, alcohols such as ethanol, methanol or isopropyl alcohol, γ-butyrolactone, or acetone can be used.

The crosslinkable, water-soluble component may be dissolved in other type of solvent provided that such a solvent should satisfy two requirements including (1) no dissolution of a resist pattern, and (2) satisfactory dissolution of a crosslinkable, water-soluble component. For instance, the component may be dissolved in an organic solvent miscible with water such as N-pyrrolidone. Moreover, the material may be dissolved in a mixed solvent of two or more organic solvents miscible with water.

In the practice of the invention, the micropattern forming material may further contain, aside from the above-stated components, other types of components as additives. For example, a plasticizer such as polyvinyl acetal, ethylene glycol, glycerine, or triethylene glycol may be added. For the purpose of improving film-forming properties, surface active agents may be added. For the surface active agent, there may be used, for example, Florard (product name) of Sumitomo 3M Limited., Nonipol (Trademark) of Sanyo Chemical Industries, Ltd., and the like

Next, pre-baking treatment is carried out so as to evaporate the solvent from the micropattern forming film 5. The pre-baking treatment is effected, for example, by use of a hot plate for thermal treatment at about 85° C. for about 1 minute.

In this embodiment, after the pre-baking treatment, the resist pattern 4 formed on the semiconductor substrate 1 and the micropattern forming film 5 formed thereon are subjected to thermal treatment (mixing bake treatment, which is hereinafter referred to as MB treatment). The temperature and time of the MB treatment should be set at appropriate values depending the type of resist film and the thickness of an insolubilized layer described hereinafter. For example, a hot plate is used to carry out the MB treatment at 85 to 150° C. for 60 to 120 seconds.

By the MB treatment, an acid is generated in the resist pattern and its diffusion is facilitated, thereby supplying the acid from the resist pattern to the micropattern forming film. Upon supply of the acid to the micropattern forming film, the crosslinkable, water-soluble component present in the micropattern forming film undergoes a crosslinking reaction in the presence of the acid at a portion of the micropattern forming film in contact with the resist pattern. This causes the micropattern forming film to be insolubilized in water or an alkaline aqueous developer. On the other hand, no crosslinking reaction takes place at a region of the micropattern forming film except the portion contacting with the resist pattern, so that that region is left soluble in water or an alkaline aqueous developer. It will be noted that in the invention, the portion of the micropattern forming film in contact with the resist pattern means an interface between the resist pattern and the micropattern forming film and the vicinity of the interface.

The invention is characterized in that while making use of the crosslinking reaction, a portion, which is rendered insoluble in a liquid developer, (hereinafter referred to as an insolubilized layer) is formed within the micropattern forming film. As shown in FIG. 2E, the insolubilized layer 6 is formed inside the micropattern forming film 5 so as to cover the resist pattern 4 therewith.

The invention is characterized in that the crosslinking reaction between the resist film and the micropattern forming material is carried out not only through a hydroxyl group (—OH), but also through a carboxyl group (—COOH). In this regard, the invention greatly differs from a conventional method wherein an insolubilized layer is fixed on a resist film only by crosslinking reaction mainly through a hydroxyl group (—OH). More specifically, the micropattern forming film according to the invention can react not only with a hydroxyl group (—OH), but also with a carboxyl group (—COOH). Accordingly, the micropattern forming material of the invention can well undergo crosslinking reaction with an acrylic resist or the like, thereby forming a micropattern forming film having a desired thickness.

In the practice of the invention, the thickness of the insolubilized layer to be formed on the resist pattern can be controlled by controlling the crosslinking reaction occurring in the micropattern forming film.

The technique of controlling the crosslinking reaction includes (1) a technique of controlling process conditions, and (2) a technique of controlling the composition of the micropattern forming material.

The technique of controlling process conditions includes a method wherein MB treating conditions are changed. In particular, the control of a heating time in the MB treatment is effective in controlling the thickness of the insolubilized layer. For the technique of controlling the composition of a micropattern forming material, mention is made of a method wherein two or more appropriate, crosslinkable, water-soluble components are mixed, and the mixing ratios thereof are controlled to control the quantity of reaction.

It should be noted that the control of the crosslinking reaction is not determined only by one factor, but should be determined while taking into account various factors including (1) the reactivity between the resist pattern and the micropattern forming film, (2) the shape of the resist pattern, (3) the thickness necessary for the insolubilized layer, (4) applicable MB conditions, and (5) coating conditions. Of these, the reactivity between the resist pattern and the micropattern forming layer is influenced by the type of resist composition. Accordingly, where the invention is actually applied to, it is preferred to determine the composition of the micropattern forming material while taking the above factors into account. More specifically, the types and compositional ratio of crosslinkable, water-soluble components used for the micropattern forming material are not critical, and they should preferably be optimized depending on the type of resist composition used and thermal treating conditions.

Next, development treatment is carried out using water or an alkaline liquid developer to remove the micropattern forming film 5 at portions where not undergoing crosslinking reaction. For the alkaline liquid developer, an aqueous solution of an alkali such as TMAH (tetramethylammonium hydroxide) may be used. After the development, post-baking treatment is performed under appropriate conditions to form a micropattern 7, thereby providing a structure of FIG. 2F. The post-baking treatment can be carried out, for example, by heating at 90 to 110° C. for 70 to 90 seconds.

According to the steps stated hereinabove, a micropattern that has a reduced number of defects such as bridging and is reduced in the hole inner diameter of a hole pattern or in the isolation width of a line pattern, or a micropattern wherein an island pattern is enlarged in area can be obtained. When using such a micropattern as a mask, a semiconductor device having different types of fine structures can be fabricated by etching an underlying semiconductor substrate or different types of thin films, such as an insulating film, formed on a semiconductor substrate.

In this embodiment, the instance of forming a micropattern on a semiconductor substrate has been stated, which should not be construed as limiting the invention thereto. So far as the technique is applied to the formation of a micropattern, the micropattern may be formed on other type of support. Alternatively, a micropattern may be formed on a thin film formed on a support. For instance, a mictopattern may be formed on an insulating film such as a silicon oxide film or on a conductive film such as a polysilicon film, which depends on the step of making a semiconductor device.

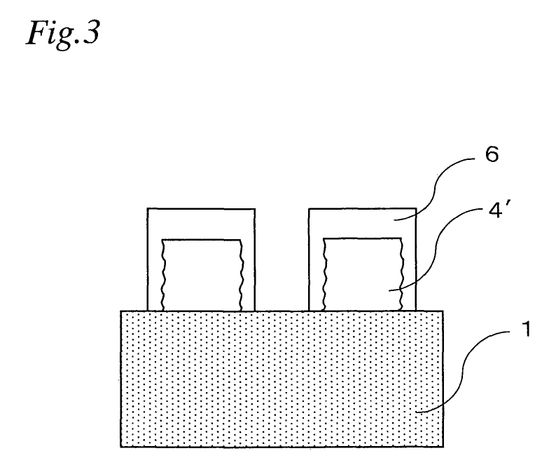

According to the invention, as shown in FIG. 3, in a case where a resist pattern 4′ formed, for example, in a semiconductor substrate 1 has irregularities in sectional form and is not good at linearity, the pattern is covered with an insolubilized layer 6, so that there can be obtained a micropattern having a sharp form in section. Accordingly, where a micropattern according to the invention is formed, for example, on an oxide film, the etching of the underlying oxide film through the mask of this micropattern enables one to obtain an oxide film pattern of good patterning properties.

As stated hereinabove, according to this embodiment, after the micropattern forming film has been insolubilized in the vicinity of the interface between the resist pattern and the micropattern forming film, the micropattern forming film at portions which remain non-insolubilized is removed, so that a micropattern can be formed beyond the limit of an exposure wavelength.

When semiconductor base materials such as an underlying semiconductor substrate or different types of thin films formed on a semiconductor substrate are etched using the micropattern as a mask, a fine hole pattern or a fine space pattern can be formed to make a semiconductor device

### Second Embodiment

This embodiment is characterized in that light exposure is carried out prior to the MB treatment set out in the first embodiment.

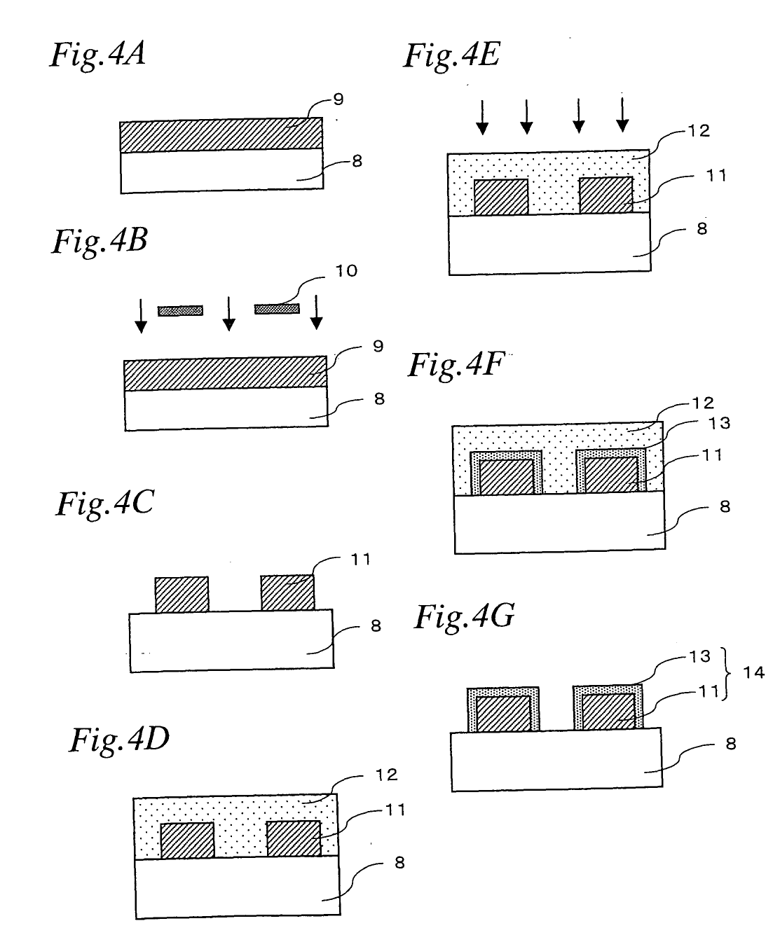

FIGS. 4A to 4G are process charts showing an instance of a method of manufacturing a semiconductor device according to the present invention. The steps of FIGS. 4A to 4D are carried out in the same manner as the steps of FIGS. 2A to 2D. More specifically, a resist composition is coated onto a semiconductor substrate 8 to form a resist film 9, followed by exposure to light via a mask 10 to form a resist pattern 11. The resist composition used in this embodiment may be a chemically amplified resist capable of generating an acid by exposure.

Next, after formation of a micropattern forming film 12 shown in FIG. 4D, the semiconductor substrate 8 is subjected to whole surface exposure by use of the g-line or i-line spectrum of a Hg lamp as shown in FIG. 4E. In this way, an acid can be generated in the resist pattern in place of the MB treatment or prior to the MB treatment.

The light source used for the exposure is not critical in type provided that it is able to generate an acid in the resist pattern and may be a light source other than a mercury lamp. For example, exposure may be carried out by use of a KrF excimer laser beam, an ArF excimer laser beam and the like.

This embodiment is characterized in that after the formation of the micropattern forming film on the resist pattern, light is exposed thereto to generate an acid in the resist pattern. More specifically, light is exposed in such a condition that the resist pattern is covered with the micropattern forming film. Accordingly, the amount of the acid being generated can be exactly controlled within a wide range by controlling the exposure, which makes it possible to precisely control the thickness of a subsequently formed insolubilized layer.

The method of forming a micropattern according to the embodiment is particularly suited for the case where both resist pattern and micropattern forming film are relatively low in reactivity or where the thickness of a required insolubilized layer is relatively large, or where crosslinking reaction is caused to uniformly occur throughout a semiconductor substrate.

Next, if necessary, the resist pattern 11 formed on the semiconductor substrate 8 and the micropattern forming film 12 formed thereon are subjected to MB treatment. The MB treatment permits the diffusion of the acid in the resist pattern to be promoted thereby supplying the acid from the resist pattern to the micropattern forming film. This causes crosslinking reaction to occur at a portion of the resist pattern in contact with the micropattern forming film thereby insolubilizing the micropattern forming film at the portion. The MB treatment should be set at optimum conditions depending on the type of resist composition used and the thickness necessary for the insolubilized layer. For instance, a hot plate may be used to provide the MB treating conditions of 60 to 130° C. and 60 to 120 seconds. When the MB treatment is carried out, the insolubilized layer 13, which is insolubilized by polar change, is formed inside the micropattern forming film 12 so as to cover the resist pattern 11 therewith as is particularly shown in FIG. 4F.

Next, developing treatment is carried out by use of water or an alkaline liquid developer to remove the micropattern forming film at non-insolubilized portions thereof. For a liquid developer, an alkaline aqueous solution such as of TMAH (tetramethylammonium hydroxide) may be used. After the development, post-baking treatment is performed under appropriate conditions to form a micropattern 14 thereby providing a structure of FIG. 4G. The post-baking treatment can be carried out by application of heat at 90 to 110° C. for 70 to 90 seconds.

According to the steps set out hereinabove, it becomes possible to obtain a micropattern that has a reduced number of defects such as bridging and is reduced in the hole inner diameter of a hole pattern or in the isolation width of a line pattern, or a micropattern wherein an island pattern is enlarged in area. Accordingly, when using this micropattern as a mask, a semiconductor device having different types of fine structures can be fabricated by etching an underlying semiconductor substrate or different types of thin films, such as an insulating film, formed on a semiconductor substrate.

According to this embodiment, the crosslinking reaction taking place in the micropattern forming film can be controlled by controlling-an exposure irradiated on the resist pattern. More specifically, for a method of controlling the crosslinking reaction by controlling such process conditions as set forth in the first embodiment, mention is made, aside from a method wherein MB conditions are changed, of a method of changing an exposure according to this embodiment.

It will be noted that in this embodiment, the instance of forming the micropattern on the semiconductor substrate has been stated, to which the invention should not be construed as limited. So far as this technique is used for the purpose of forming a micropattern, such a micropattern may be formed on other type of support. Alternatively, a micropattern may be formed on a thin film formed on a support. For instance, a micropattern may be formed on an insulating film such as a silicon oxide film or on a conductive film such as a polysilicon film depending on the fabrication step of a semiconductor device.

According to the invention, if patterning properties of an underlying resist pattern are not good, the formation of a micropattern forming film enables one to obtain a micropattern having a sharp form in section. For example, where a micropattern according to the invention is formed on an oxide film and the underlying oxide film is etched through the mask of this micropattern, an oxide film pattern of good patterning properties can be obtained.

As stated hereinabove, according to this embodiment, the micropattern forming film is insolubilized in the vicinity of the interface between the resist pattern and the micropattern forming film, after which the micropattern forming film at portions where not insolubilized is removed, so that a micropattern can be formed beyond the limit of an exposure wavelength.

Moreover, where exposure is performed prior to the MB treatment, the insolubilization reaction of the micropattern forming film can be more facilitated. In other words, a thicker insolubilized layer can be formed, thus leading to the possibility of forming a finer micropattern.

Further, a fine hole pattern or a fine space pattern can be formed by etching a semiconductor base material, such as an underlying semiconductor substrate or different types of thin films, formed on a semiconductor substrate through the mask of a micropattern, thereby making a semiconductor device.

### Third Embodiment

This embodiment is characterized in that after the formation of a resist pattern, a desired region of a semiconductor substrate is subjected to light exposure.

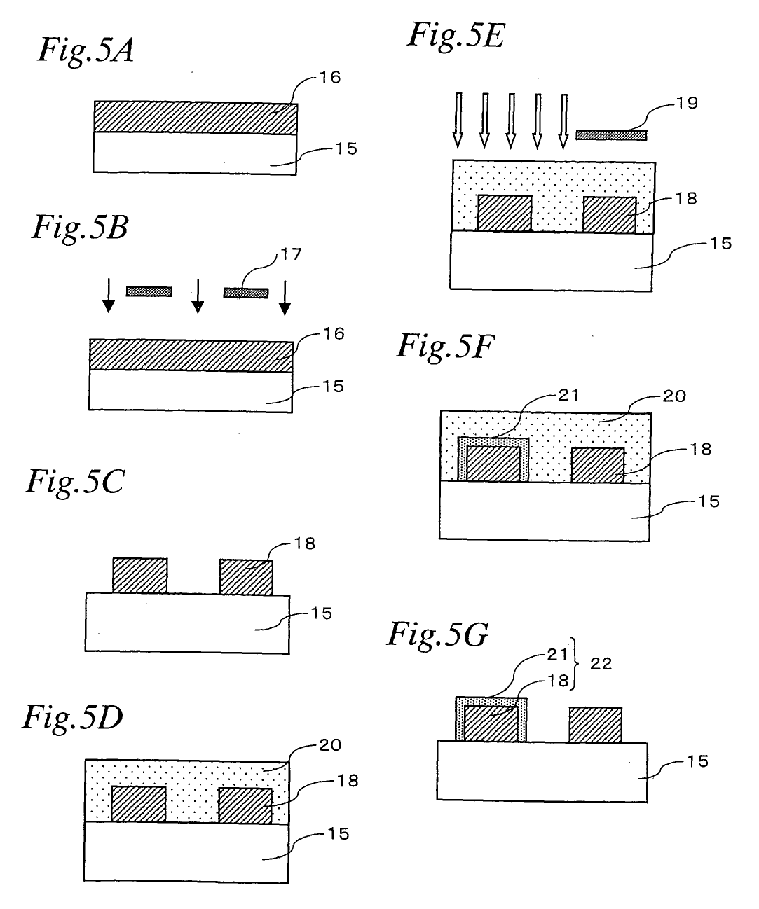

FIGS. 5A to 5G are process charts showing a method of manufacturing a semiconductor device according to the present invention. The steps of FIGS. 5A to 5D are carried out in the same manner as those of FIGS. 2A to 2D. More specifically, a resist composition is coated onto a semiconductor substrate 15 to form a resist film 16, followed by exposure through a mask 17 to form a resist pattern 18. The resist composition used in this embodiment may be a chemically amplified resist capable of generating an acid by exposure.

Next, after formation of a micropattern forming film 20 shown in FIG. 5D, the resist pattern 18 is selectively exposed by use of-an appropriate light-shielding plate 19 in a manner as shown in FIG. 5E. For the exposure, a g-line spectrum or i-line spectrum of a Hg lamp may be used, for example. In this manner, an acid can be generated only at the selectively exposed portions of the resist pattern. Thereafter, heat treatment may be carried out, if necessary, in order to facilitate the crosslinking reaction. In this connection, care should be so paid as not to permit the acid to be diffused into a region other than the selected region.

The light source used for the exposure is not critical in type provided that it is able to generate an acid in the resist pattern. A light source other than a mercury lamp may be used. For instance, a KrF excimer laser beam, an ArF excimer laser beam and the like may be used for the exposure. The type of light source and the exposure that depend on the sensitivity wavelength of the resist pattern should be appropriately selected.

According to this embodiment, as shown in FIG. 5F, the crosslinking reaction takes place only at the exposed portion among portions where the resist pattern 18 and the micropattern forming film 20 are in contact with each other, thereby forming an insolubilized layer 21. On the other hand, with respect to a region other than the portions in contact with the resist pattern 18, no crosslinking reaction takes place, and thus no insolubilized layer is formed at all. In addition, with respect to a portion which is in contact with the resist pattern 18 but not exposed, no crosslinking reaction occurs and no insolubilized layer is formed as well. In other words, the insolubilized layer 21 is formed only in the exposed portion of the micropattern forming film 20 so as to cover the resist pattern 18 therewith.

Next, developing treatment is carried out by use of water or an alkaline liquid developer to remove the micropattern forming film 20 at portions where not insolubilized. For the alkaline liquid developer, an aqueous solution of an alkali such as TMAH (tetramethylammonium hydroxide) may be used. After the development, post-baking is performed under appropriate conditions to form a micropattern 22, thereby providing a structure of FIG. 5G. The post-baking may be performed, for example, by heating at 90 to 110° C. for about 70 to 90 seconds by use of a hot plate.

According to the steps set forth hereinabove, it becomes possible to obtain a micropattern that has a reduced number of defects such as bridging and is reduced in the hole inner diameter of a hole pattern or in the isolation width of a line pattern, or a micropattern wherein an island pattern is enlarged in area. Accordingly, when using this micropattern as a mask, a semiconductor device having different types of fine structures can be fabricated by etching an underlying semiconductor substrate or different types of thin films, such as an insulating film, formed on a semiconductor substrate.

It will be noted that in this embodiment, the instance of forming the micropattern on the semiconductor substrate has been stated, to which the invention should not be construed as limited. So far as the technique is used for the purpose of forming a micropattern, such a micropattern may be formed on other type-of support. Alternatively, a micropattern may be formed on a thin film formed on a support. For instance, a micropattern may be formed on an insulating film such as a silicon oxide film or on a conductive film such as a polysilicon film depending on the fabrication step of a semiconductor device.

According to the invention, if patterning properties of an underlying resist pattern are not good, the formation of a micropattern forming film enables one to obtain a micropattern having a sharp form in section. For example, where a micropattern according to the invention is formed on an oxide film and the underlying oxide film is etched through the mask of this micropattern, an oxide film pattern of good patterning properties can be obtained.

As stated hereinabove, according to this embodiment, the micropattern forming film is insolubilized in the vicinity of the interface between the resist pattern and the micropattern forming film, after which the micropattern forming film at portions where not insolubilized is removed, so that a micropattern can be formed beyond the limit of an exposure wavelength.

Moreover, where exposure is performed only at the selected region of the semiconductor substrate, the insolubilized layer can be formed only at this selected region. Thus, micropatterns having different sizes can be formed on the same semiconductor substrate.

Further, a fine hole pattern or a fine space pattern can be formed by etching a semiconductor base material, such as an underlying semiconductor substrate or different types of thin films formed on a semiconductor substrate, through the mask of a micropattern, thereby making a semiconductor device.

### Fourth Embodiment

This embodiment is characterized in that after formation of a resist pattern, an electron beam is directed only to a desired region of a semiconductor substrate.

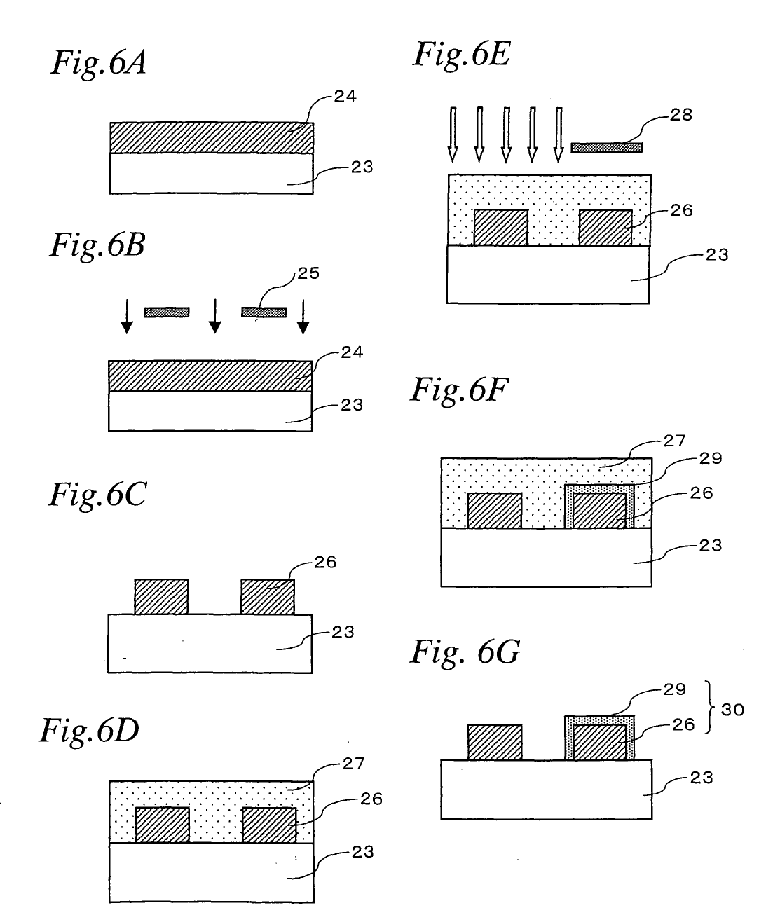

FIGS. 6A to 6G are process charts showing an instance of a method of manufacturing a semiconductor device according to this embodiment. The steps of FIGS. 6A to 6D are carried out in the same manner as in FIGS. 2A to 2D. More specifically, a resist composition is coated onto a semiconductor substrate 23 to form a resist film 24, followed by exposure through a mask 25 to form a resist pattern 26. The resist composition used in this embodiment may be, for example, such a resist composition as used in the first embodiment.

Next, after formation of a micropattern forming film 27 shown in FIG. 6D, the selected region of the resist pattern 26 is shielded with an appropriate electron beam-shielding plate 28 as shown in FIG. 6E, followed by irradiation of an electron beam against the other region.

Subsequently, thermal treatment is carried out to cause crosslinking reaction to take place only at the electron beam-shielded portion among portions where the resist pattern 26 and the micropattern forming film are in contact with each other, thereby forming an insolubilized layer 29. The thermal treatment is performed by use, for example, of a hot plate by heating at 70 to 150° C. for 60 to 120 seconds. On the other hand, the portion in which the resist pattern 26 and the micropattern forming film 27 are in contact with each other and to which an electron beam is directed does not undergo crosslinking reaction, thereby not forming an insolubilized layer. In other words, the insolubilized layer 29 is formed in the micropattern forming film 27 at the shielded portion thereof so as to cover the resist pattern 26 therewith.

Next, developing treatment is carried out by use of water or an alkaline liquid developer to remove the micropattern forming film 27 at portions where not insolubilized. For the alkaline liquid developer, an aqueous solution of an alkali such as TMAH (tetramethylammonium hydroxide) may be used. After the development, post-baking is performed under appropriate conditions to form a micropattern 30, thereby providing a structure of FIG. 6G. The post-baking may be performed, for example, by heating at 90 to 110° C. for about 70 to 90 seconds by use of a hot plate.

According to the steps set forth hereinabove, it becomes possible to obtain a micropattern that has a reduced number of defects such as bridging and is reduced in the hole inner diameter of a hole pattern or in the isolation width of a line pattern, or a micropattern wherein an island pattern is enlarged in area. Accordingly, when using this micropattern as a mask, a semiconductor device having different types of fine structures can be fabricated by etching an underlying semiconductor substrate or different types of thin films, such as an insulating film, formed on a semiconductor substrate.

It will be noted that in this embodiment, the instance of forming the micropattern on the semiconductor substrate has been stated, to which the invention should not be construed as limited. So far as the technique is used for the purpose of forming a micropattern, such a micropattern may be formed on other type of support. Alternatively, a micropattern may be formed on a thin film formed on a support. For instance, a micropattern may be formed on an insulating film such as a silicon oxide film or on a conductive film such as a polysilicon film depending on the fabrication step of a semiconductor device.

According to the invention, if patterning properties of an underlying resist pattern are not good, the formation of a micropattern forming film enables one to obtain a micropattern having a sharp form in section. For example, where a micropattern according to the invention is formed on an oxide film and the underlying oxide film is etched through the mask of this micropattern, an oxide film pattern of good patterning properties can be obtained.

As stated hereinabove, according to this embodiment, the micropattern forming film is insolubilized in the vicinity of the interface between the resist pattern and the micropattern forming film, after which the micropattern forming film at portions where not insolubilized is removed, so that a micropattern can be formed beyond the limit of an exposure wavelength.

Moreover, where exposure is performed except at the selected region of the semiconductor substrate, the insolubilized layer can be formed only at this selected region. Thus, micropatterns having different sizes can be formed on the same semiconductor substrate.

Further, a fine hole pattern or a fine space pattern can be formed by etching a semiconductor base material, such as an underlying semiconductor substrate or different types of thin films formed on a semiconductor substrate, through the mask of a micropattern, thereby making a semiconductor device.

### Fifth Embodiment

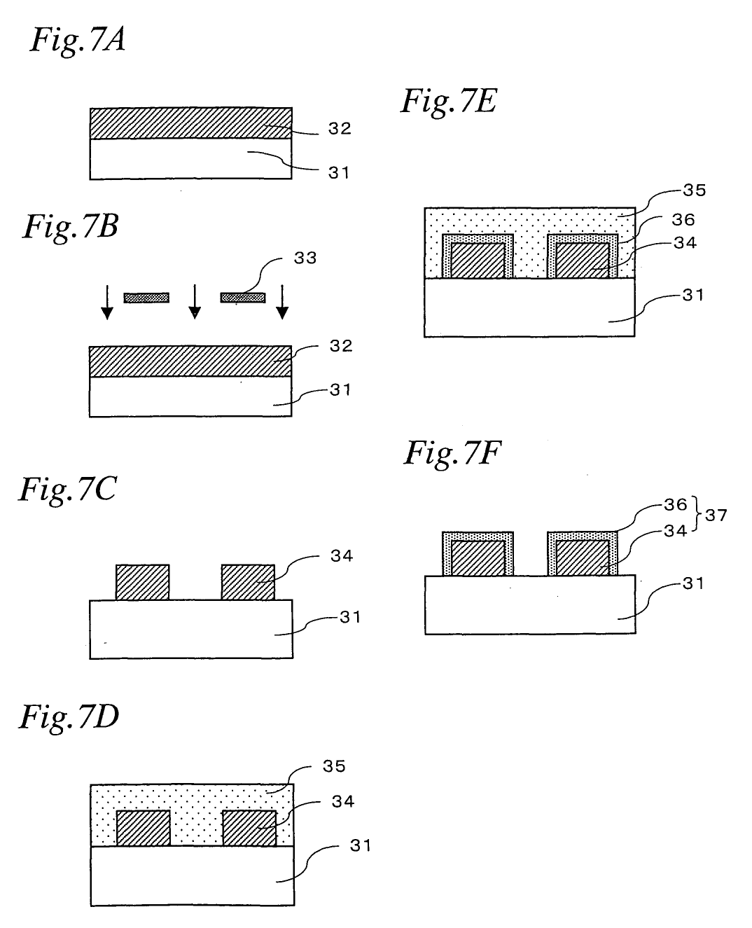

FIGS. 7A to 7F are process charts showing an instance of a method of manufacturing a semiconductor device according to this embodiment.

Initially, as shown in FIG. 7A, a resist composition is coated onto a semiconductor substrate 31 to form a resist film 32. For instance, a resist composition is applied onto a semiconductor substrate by use of a spin coating method in a thickness of about 0.7 to 1.0 μm.

The resist composition used in this embodiment includes a positive type resist composed of an acrylic resin, a novolac resin and a naphthoquinone diazide photosensitizer, and a chemically amplified resist capable of generating an acid by application of heat. The resist composition may be made of either a positive type resist or a negative type resist.

This embodiment is characterized in that the resist composition contains a slight amount of an acidic substance in the inside thereof. For the acidic substance, a low molecular weight acid based on a carboxylic acid is preferred, but other types of substances may be used provided that they can be mixed with the resist composition, and thus specific limitation is not placed on the type thereof.

Next, the solvent present in the resist film 32 is evaporated by pre-baking treatment. The pre-baking treatment is carried out, for example, by thermal treatment using a hot plate at 70 to 110° C. for about 1 minute. Thereafter, as shown in FIG. 7B, the resist film 32 is exposed to light through a mask 33 including such a pattern as shown in FIGS. 1A to 1C. The light source used for the exposure may be one whose wavelength corresponds to a sensitivity wavelength of the resist film 32. Using such a light source, the-resist film 32 is irradiated, for example, with a g-line spectrum, an i-line spectrum, deep UV light, a KrF excimer laser beam (248 nm), an ArF excimer laser beam (193 nm) and EB (electron beam), an X ray or the like.

After exposure of the resist film, PEB treatment (post-exposure baking treatment) is carried out, if necessary. This leads to an improved resolution of the resist film. The PEB treatment is performed, for example, by baking at 50 to 130° C.

Next, developing treatment is carried out by use of an appropriate liquid developer for patterning of the resist film 32. If the resist composition used is of the positive type, such a resist pattern 34 as shown in FIG. 7C is obtained. For the liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60 to 120° C. for about 60 seconds.

As shown in FIG. 7D, a micropattern forming material according to the invention is coated onto the resist pattern 34 to form a micropattern forming film 35. The manner of coating the micropattern forming material is not critical so far as uniform coating on the resist pattern 34 is ensured. For instance, a spraying method, a spin coating method or the like can be used for the coating. Alternatively, a semiconductor device having such a structure as in FIG. 7C may be immersed (dipped) in a micropattern forming material to form a micropattern forming film 35 on the resist pattern 34.

The micropattern forming material of the invention should be one which undergoes crosslinking reaction in the presence of an acid and is rendered insoluble in a liquid developer. For the micropattern forming material used in this embodiment, those set out in the first embodiment can be used.

Next, pre-baking treatment is carried out to evaporate the solvent present in the micropattern forming film 35. The pre-baking treatment is effected, for example, by use of a hot plate for baking or thermal treatment at approximately 85° C. for about 1 minute.

After the pre-baking treatment, the resist pattern 34 formed on the semiconductor substrate 31 and the micropattern forming film 35 formed thereon are subjected to MB treatment. The temperature and time of the MB treatment should be set at appropriate values depending on the type of resist film and the thickness of an insolubilized layer described hereinafter. For instance, thermal treatment at 60 to 130° C. may be carried out for this purpose.

The acid contained in the resist pattern is diffused through the MB treatment, thereby permitting the acid to be supplied from the resist pattern to the micropattern forming film. When the acid is supplied to the micropattern forming film, the crosslinkable, water-soluble component present in the micropattern forming film undergoes crosslinking reaction in the presence of the acid at a portion where the resist pattern and the micropattern forming film are in contact with each other. In this way, the micropattern forming film is rendered insoluble in water or an alkaline aqueous developer. On the other hand, no crosslinking reaction takes place at a region other than the portion of the micropattern forming film in contact with the resist pattern, and the region remains as soluble in water or an alkaline aqueous developer.

According to the steps set out hereinabove, the insolubilized layer 36 is formed in the micropattern forming film 35 so as to cover the resist pattern 34 therewith as shown in FIG. 7E.

Next, developing treatment is carried out by use of water or an alkaline liquid developer to remove the micropattern forming film 35 at portions where not insolubilized. For the alkaline liquid developer, an aqueous solution of an alkali such as TMAH (tetramethylammonium hydroxide) may be used. After the development, post-baking is performed under appropriate conditions to form a micropattern 37, thereby providing a structure of FIG. 7F. The post-baking may be performed, for example, by heating at 90 to 110° C. for about 70 to 90 seconds by use of a hot plate.

According to the steps set forth hereinabove, it becomes possible to obtain a micropattern that has a reduced number of defects such as bridging and is reduced in the hole inner diameter of a hole pattern or in the isolation width of a line pattern, or a micropattern wherein an island pattern is enlarged in area. Accordingly, when using this micropattern as a mask, a semiconductor device having different types of fine structures can be fabricated by etching an underlying semiconductor substrate or different types of thin films, such as an insulating film, formed on a semiconductor substrate.

It will be noted that in this embodiment, the instance of forming the micropattern on the semiconductor substrate has been stated, to which the invention should not be construed as limited. So far as the technique is used for the purpose of forming a micropattern, such a micropattern may be formed on other type of support. Alternatively, a micropattern may be formed on a thin film formed on a support. For instance, a micropattern may be formed on an insulating film such as a silicon oxide film or on a conductive film such as a polysilicon film depending on the fabrication step of a semiconductor device.

According to the invention, if patterning properties of an underlying resist pattern are not good, the formation of a micropattern forming film enables one to obtain a micropattern having a sharp shape in section. For example, where a micropattern according to the invention is formed on an oxide film and the underlying oxide film is etched through the mask of this micropattern, an oxide film pattern of good patterning properties can be obtained.

As stated hereinabove, according to this embodiment, the micropattern forming film is insolubilized in the vicinity of the interface between the resist pattern and the micropattern forming film, after which the micropattern forming film at portions where not insolubilized is removed, so that a micropattern can be formed beyond the limit of an exposure wavelength.

Moreover, since an acid is contained in the resist composition, it is not necessary to generate an acid through the exposure step. After insolubilization of the micropattern forming film at the interface between the resist pattern and the micropattern forming film, the non-insolubilized portion of the micropattern forming film is removed, so that such a micropattern exceeding the limit of the exposure wavelength can be formed.

Further, a fine hole pattern or a fine space pattern can be formed by etching a semiconductor base material, such as an underlying semiconductor substrate or different types of thin films formed on a semiconductor substrate, through the mask of a micropattern, thereby making a semiconductor device.

### Sixth Embodiment

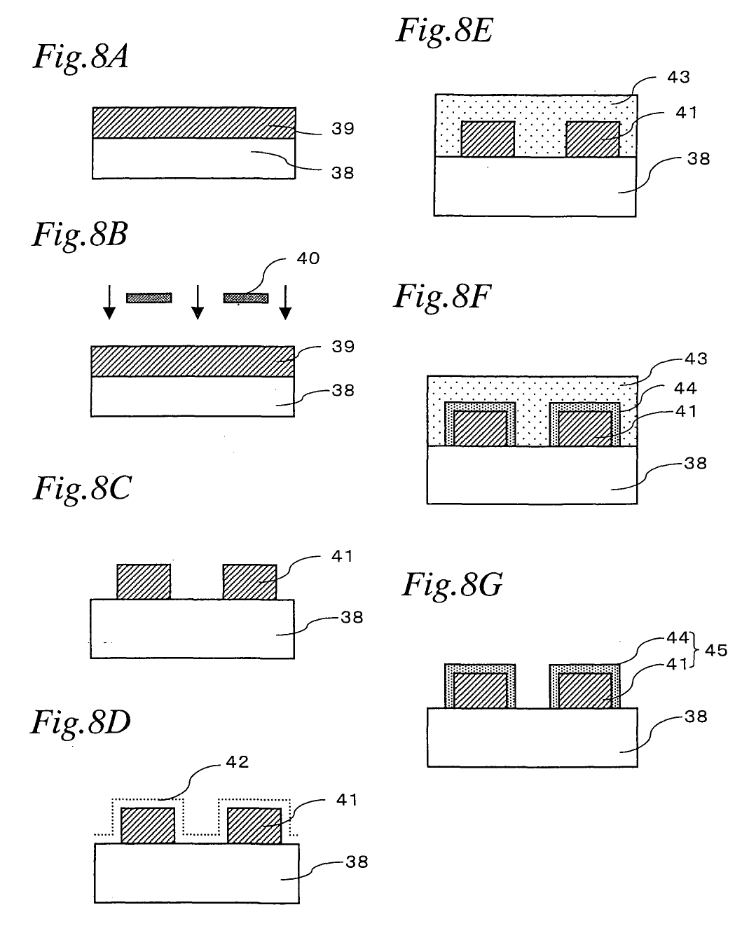

FIGS. 8A to 8G show an instance of a method of fabricating a semiconductor device according to this embodiment.

As shown in FIG. 8A, a resist composition is coated onto a semiconductor substrate 38 to form a resist film 39. For instance, the resist composition is coated onto a semiconductor substrate by a spin coating method in a thickness of about 0.7 to 1.0 μm.

For the resist composition used in this embodiment, those stated in the first embodiment are effectively used.

Next, the solvent present in the resist film 39 is evaporated by pre-baking treatment. The pre-baking treatment is carried out, for example, by thermal treatment using a hot plate at 70 to 110° C. for about 1 minute. Thereafter, as shown in FIG. 8B, the resist film 39 is exposed to light through a mask 40 including such a pattern as shown in FIGS. 1A to 1C. The light source used for the exposure may be one whose wavelength corresponds to a sensitivity wavelength of the resist film 39. Using such a light source, the resist film 39 is irradiated, for example, with a g-line spectrum, an i-line spectrum, deep UV light, a KrF excimer laser beam (248 nm), an ArF excimer laser beam (193 nm) and EB (electron beam), an X ray or the like.

After exposure of the resist film, PEB treatment (post-exposure baking treatment) is carried out, if necessary. This leads to an improved resolution of the resist film. The PEB treatment is performed, for example, by baking at 50 to 130° C.

Next, developing treatment is carried out by use of an appropriate liquid developer for patterning of the resist film 39. If the resist composition used is of the positive type, such a resist pattern 41 as shown in FIG. 8C is obtained. For the liquid developer, an alkaline aqueous solution containing, for example, about 0.05 to 3.0 wt % of TMAH (tetramethylammonium hydroxide) may be used.

After completion of the development, post-development baking may be performed, if necessary. Because the post-development baking influences a subsequent mixing reaction, it is favorable that temperature conditions are appropriately set depending on the types of resist composition and micropattern-forming material used. For instance, a hot plate is used for heating at 60 to 120° C. for about 60 seconds.

Next, a semiconductor device having such a structure of FIG. 8C is treated with an acidic solution or an acidic gas. For instance, it may be dipped in an acidic solution or may be treated according to a technique like a paddle phenomenon. Alternatively, an acidic solution may be vaporized (or blown) against a semiconductor device. In this case, the acidic solution or acidic gas may be made of either an organic acid or an inorganic acid. More specifically, acetic acid of a low concentration may be mentioned as a preferred instance.

When the semiconductor device is treated with an acidic solution or acidic gas, a thin layer 42 containing an acid is formed on the surface of a resist pattern 41 as shown in FIG. 8D. (It will be noted that the acid-containing thin layer 42 is omitted in FIGS. 8E to 8G.) Thereafter, the device may be rinsed such as with pure water, if necessary.

Next, a micropattern forming material according to the invention is coated onto a resist pattern 41. In this way, a micropattern forming film 43 is formed on the resist pattern 41 as shown in FIG. 8E. The manner of coating of the micropattern forming material is not critical provided that uniform coating on the resist pattern 41 is ensured. For instance, coating is possible by use of a spraying method, a spin coating method or the like.

The micropattern forming material used should be one which undergoes crosslinking reaction in the presence of an acid and is rendered insoluble in a liquid developer. For the micropattern forming material used in this embodiment, those set out in the first embodiment may be likewise used.

Next, pre-baking treatment is carried out to evaporate the solvent present in the micropattern forming film 43. The pre-baking treatment is effected, for example, by use of a hot plate for baking at approximately 85° C. for about 1 minute.

After the pre-baking treatment, the resist pattern 41 formed on the semiconductor substrate 38 and the micropattern forming film 43 formed thereon are subjected to MB treatment. The temperature and time of the MB treatment should be set at appropriate values depending on the type of resist film and the thickness of an insolubilized layer described hereinafter. For instance, thermal treatment at 60 to 130° C. may be carried out for this purpose.

By the MB treatment, the acid is diffused from the resist pattern to the micropattern forming film. When the acid is supplied to the micropattern forming film, the crosslinkable, water-soluble component present in the micropattern forming film undergoes crosslinking reaction in the presence of the acid at a portion where the resist pattern and the micropattern forming film are in contact with each other. In this way, the micropattern forming film is rendered insoluble in water or an alkaline aqueous developer. On the other hand, no crosslinking reaction takes place at a region other than the portion of the micropattern forming film in contact with the resist pattern, and the region remains as soluble in water or an alkaline aqueous developer.

According to the steps set out hereinabove, the insolubilized layer 44 is formed in the micropattern forming film 43 so as to cover the resist pattern 41 therewith as shown in FIG. 8F.

Next, developing treatment is carried out by use of water or an alkaline liquid developer to remove the micropattern forming film 27 at portions where not insolubilized. For the alkaline liquid developer, an aqueous solution of an alkali such as TMAH (tetramethylammonium hydroxide) may be used. After the development, post-baking is performed under appropriate conditions to form a micropattern 22, thereby providing a structure of FIG. 8G. The post-baking may be performed, for example, by heating at 90 to 110° C. for about 70 to 90 seconds by use of a hot plate.

According to the steps set forth hereinabove, it becomes possible to obtain a micropattern that has a reduced number of defects such as bridging and is reduced in the hole inner diameter of a hole pattern or in the isolation width of a line pattern, or a micropattern wherein an island pattern is enlarged in area. Accordingly, when using this micropattern as a mask, a semiconductor device having different types of fine structures can be fabricated by etching an underlying semiconductor substrate or different-types of thin films, such as an insulating film, formed on a semiconductor substrate.

It will be noted that in this embodiment, the instance of forming the micropattern on the semiconductor substrate has been stated, to which the invention should not be construed as limited. So far as the technique is used for the purpose of forming a micropattern, such a micropattern may be formed on other type of support. Alternatively, a micropattern may be formed on a thin film formed on a support. For instance, a micropattern may be formed on an insulating film such as a silicon oxide film or on a conductive film such as a polysilicon film depending on the fabrication step of a semiconductor device.

According to the invention, if patterning properties of an underlying resist pattern are not good, the formation of a micropattern forming film enables one to obtain a micropattern having a sharp shape in section. For example, where a micropattern according to the invention is formed on an oxide film and the underlying oxide film is etched through the mask of this micropattern, an oxide film pattern of good patterning properties can be obtained.

As stated hereinabove, according to this embodiment, the micropattern forming film is insolubilized in the vicinity of the interface between the resist pattern and the micropattern forming film, after which the micropattern forming film at portions where not insolubilized is removed, so that a micropattern can be formed beyond the limit of an exposure wavelength.

Moreover, because the acid-containing thin layer is formed in the resist pattern surface by treating the resist pattern with an acidic solution or an acidic gas, it is not necessary to generate an acid through the exposure step.

Further, a fine hole pattern or a fine space pattern can be formed by etching a semiconductor base material, such as an underlying semiconductor substrate or different types of thin films formed on a semiconductor substrate, through the mask of a micropattern, thereby making a semiconductor device.

The formation of a micropattern according to the invention is not limited depending on the type of underlying substrate material, and any types of substrate materials may be used if a micropattern can be formed thereon.

The invention is applicable not only to a method of fabricating a semiconductor device, but also to the manufacture of other devices wherein a micropattern is formed. For instance, using a method of forming a micropattern according to the invention, other types of electronic devices such as thin film magnetic heads can be made.

### EXAMPLES

### Formation of a Resist Pattern

### Example 1

A novolac resin and naphthoquinone diazide were dissolved in a solvent consisting of ethyl lactate and propylene glycol monoethyl acetate to prepare an i-line resist, which was provided as a resist composition. Next, the resist composition was dropped on a silicon wafer and spin coated by use of a spinner. Thereafter, pre-baking was carried out at 85° C. for 70 seconds to evaporate the solvent from a resist film. The resist film after the pre-baking had a thickness of about 1.0 μm.

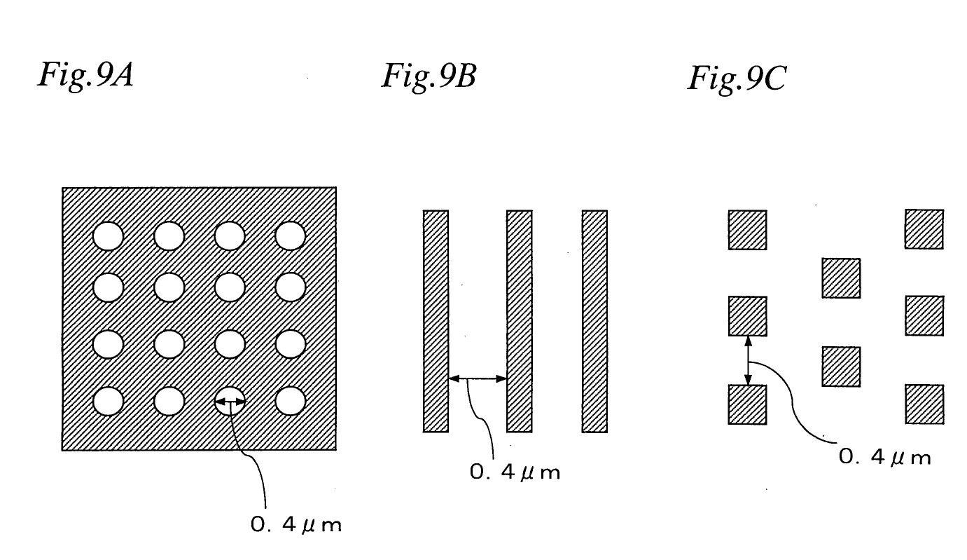

Next, the resist film was exposed to light by use of an i-line reduced projection-type aligner. Thereafter, PEB treatment was carried out at 120° C. for 70 seconds, followed by development with an alkaline liquid developer (NMD3, made by Tokyo Ohka Kogyo Co., Ltd.) to obtain a resist pattern. In FIGS. 9A to 9C, the instances of the resist pattern and an isolation width thereof are shown. It will be noted that the shaded portion means a portion wherein the resist is formed.

### Example 2

A novolac resin and naphthoquinone diazide were dissolved in a solvent of 2-heptanone to prepare an i-line resist, which was provided as a resist composition. Next, the resist composition was dropped on a silicon wafer and spin coated by use of a spinner. Thereafter, pre-baking was carried out at 85° C. for 70 seconds to evaporate the solvent from the resist film. The resist film after the pre-baking had a thickness of about 0.8 μm.

Next, the resist film was exposed to light by use of an i-line reduced projection-type aligner. An exposure mask used had a pattern shown in FIGS. 1A˜1C. Thereafter, PEB treatment was carried out at 120° C. for 70 seconds, followed by development with an alkaline liquid developer (NMD3, made by Tokyo Ohka Kogyo Co., Ltd.) to obtain a resist pattern. In FIGS. 9A to 9C, the instances of the resist pattern and an isolation width thereof are shown.

### Example 3

A novolac resin and naphthoquinone diazide were dissolved in a solvent consisting of ethyl lactate and butyl acetate to prepare an i-line resist, which was provided as a resist composition. Next, the resist composition was dropped on a silicon wafer and spin coated by use of a spinner. Thereafter, pre-baking was carried out at 100° C. for 90 seconds to evaporate the solvent from the resist film. The resist film after the pre-baking had a thickness of about 1.0 μm.

Next, the resist film was exposed to light by use of a stepper, made by Nikon Corporation. The exposure mask used was one having such a pattern as shown in FIGS. 1A to 1C. Thereafter, PEB treatment was carried out at 110° C. for 60 seconds, followed by development with an alkaline liquid developer (NMD3, made by Tokyo Ohka Kogyo Co., Ltd.) to obtain a resist pattern. In FIGS. 9A to 9C, the instances of the resist pattern and an isolation width thereof are shown.

### Example 4

For a resist composition, a chemically amplified resist, made by Tokyo Ohka Kogyo Co., Ltd., was used. Next, the resist composition was dropped on a silicon wafer and spin coated by use of a spinner. Thereafter, pre-baking was carried out at 90° C. for 90 seconds to evaporate the solvent from the resist film. The resist film after the pre-baking had a thickness of about 0.8 μm.

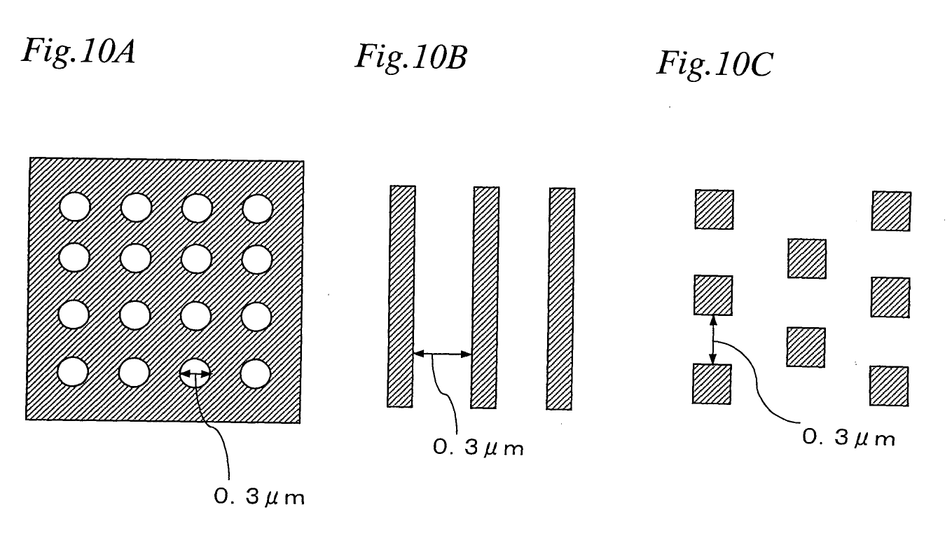

Next, the resist film was exposed to light by use of a KrF excimer reduced projection-type aligner. The exposure mask used had such a pattern as shown in FIGS. 1A to 1C. Thereafter, PEB treatment was carried out at 100° C. for 90 seconds, followed by development with an alkaline liquid developer (NMD-W, made by Tokyo Ohka Kogyo Co., Ltd.) to obtain a resist pattern. In FIGS. 10A to 10C, the instances of the resist pattern and an isolation width thereof are shown. It will be noted that the shaded portion means a portion wherein the resist is formed.

### Example 5

For a resist composition, a chemically amplified excimer resist, made by Sumitomo Kasei Corporation, was used. Next, the resist composition was dropped on a silicon wafer and spin coated by use of a spinner. Thereafter, pre-baking was carried out at 90° C. for 90 seconds to evaporate the solvent from the resist film. The resist film after the pre-baking had a thickness of about 0.8 μm.

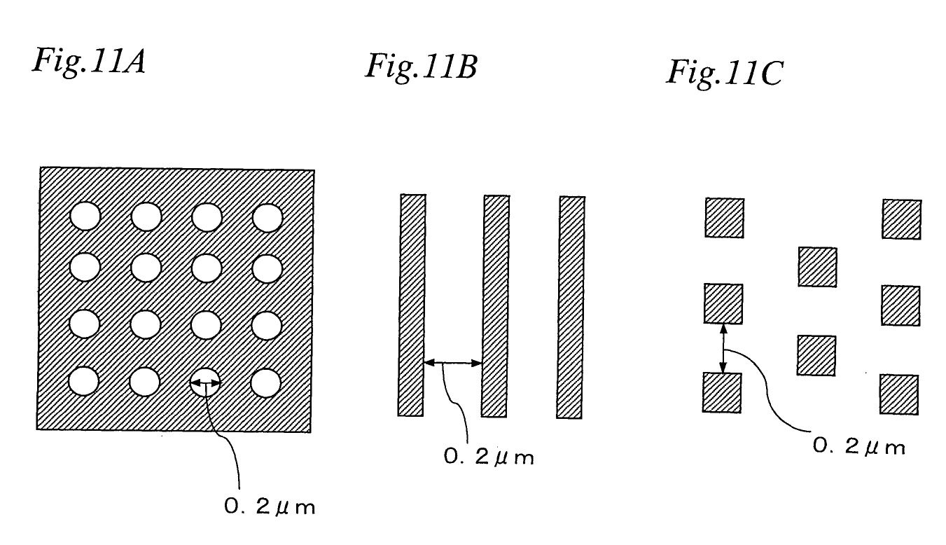

Next, the resist film was exposed to light by use of an ArF excimer reduced projection-type aligner. The exposure mask used had such a pattern as shown in FIGS. 1A˜1C. Thereafter, PEB treatment was carried out at 100° C. for 90 seconds, followed by development with an alkaline liquid developer of TMAH (NMD-W, made by Tokyo Ohka Kogyo Co., Ltd.) to obtain a resist pattern. In FIGS. 11A to 11C, the instances of the resist pattern and an isolation width thereof are shown. It will be noted that the shaded portion indicates a portion wherein the resist is formed.

### Example 6

For a resist composition, a chemically amplified resist (MELKER, J. Vac. Sci. Technol., B11 (6) 2773, 1993), made by Ryouden Chemicals, Ltd., containing t-butoxycarbonylated polyhydroxystyrene and an acid generator was used. Next, the resist composition was dropped on a silicon wafer and spin coated by use of a spinner. Thereafter, pre-baking was carried out at 120° C. for 180 seconds--to evaporate the solvent from the resist film. The resist film after the pre-baking had a thickness of about 0.52 μm.

Next, for the purpose of forming an antistatic film, Espacer ESP-100, made by Showa Denko K.K., was dropped on the resist film and spin coated by use of a spinner. Thereafter, pre-baking was carried out at 80° C. for 120 seconds.

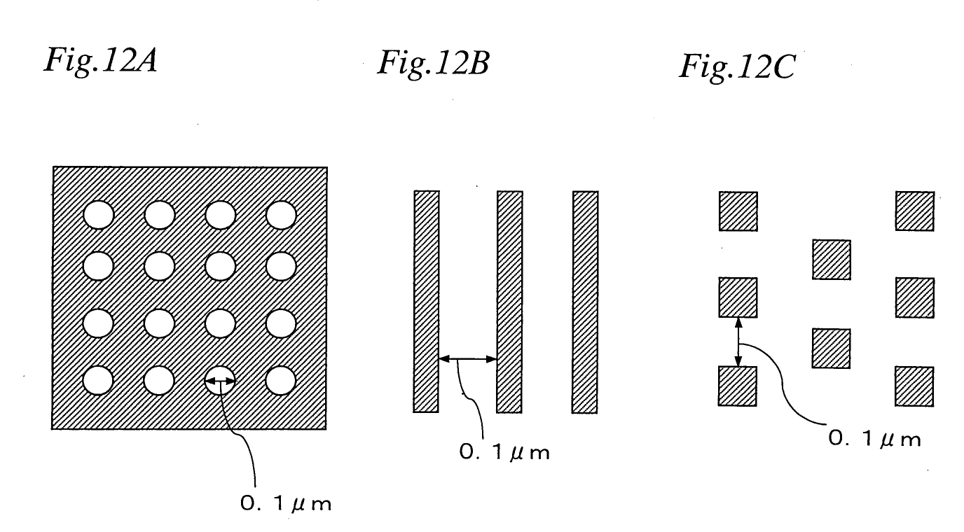

Next, an EB drawing device was used for drawing at a dosage of 17.4 μC/cm². Thereafter, PEB treatment was carried out at 80° C. for 120 seconds, after which the antistatic film was removed by use of pure water, followed by development with an alkaline liquid developer of TMAH (NMD-W, made by Tokyo Ohka Kogyo Co., Ltd.) to obtain a resist pattern. In FIGS. 12A to 12C, an instance of the resist pattern and an isolation width thereof is shown. It will be noted that the shaded portion means a portion wherein the resist is formed.

### Preparation of a Micropattern Forming Material

### Example 7

90 g of an ethyleneimine oligomer (product name: SP-003), made by Nippon Shokubai Co., Ltd., was placed in a one liter measuring flask, to which 10 g of pure water was added. The mixture was agitated and mixed at room temperature for 6 hours to obtain an aqueous solution of 90 wt % of the ethyleneimine oligomer.

### Example 8

90 g of an ethyleneimine oligomer (product name: SP-018), made by Nippon Shokubai Co., Ltd., was placed in a one liter measuring flask, to which 10 g of pure water was added. The mixture was agitated and mixed at room temperature for 6 hours to obtain an aqueous solution of 90 wt % of the ethyleneimine oligomer.

### Example 9

90 g of an ethyleneimine oligomer (product name: SP-200), made by Nippon Shokubai Co., Ltd., was placed in a one liter measuring flask, to which 10 g of pure water was added. The mixture was agitated and mixed at room temperature for 6 hours to obtain an aqueous solution of 90 wt % of the ethyleneimine oligomer.

### Example 10

90 g of an allylamine oligomer (product name: PAA-01), made by Nitto Boseki Co., Ltd., was placed in a one liter measuring flask, to which 10 g of pure water was added. The mixture was agitated and mixed at room temperature for 6 hours to obtain an aqueous solution of 90 wt % of the allylamine oligomer.

### Example 11

90 g of an allylamine oligomer (product name: PAA-03), made by Nitto Boseki Co., Ltd., was placed in a one liter measuring flask, to which 10 g of pure water was added. The mixture was agitated and mixed at room temperature for 6 hours to obtain an aqueous solution of 90 wt % of the allylamine oligomer.

### Example 12

90 g of an allylamine oligomer (product name: PAA-05), made by Nitto Boseki Co., Ltd., was placed in a one liter measuring flask, to which 10 g of pure water was added. The mixture was agitated and mixed at room temperature for 6 hours to obtain an aqueous solution of 90 wt % of the allylamine oligomer.

### Example 13

0.4 g, 1.8 g, 5.6 g, 11 g and 22 g of the aqueous solution of ethyleneimine oligomer (product name: SP-003) obtained in Example 7 were further admixed with 40 g, 55 g, 97 g, 159 g and 283 g, respectively. Next, 100 g of a 10 wt % polyvinyl acetal aqueous solution was added, as a plasticizer, to these aqueous solutions, respectively, followed by mixing under agitation at room temperature for 6 hours. As a result, five types of mixed solutions having ethyleneimine oligomer concentrations, relative to the plasticizer, of about 4 wt %, 16 wt %, 50 wt %, 100 wt % and 200 wt %, respectively, were obtained.

### Example 14

Three types of solutions were prepared wherein 30 g, 60 g and 90 g of the aqueous solution of ethyleneimine oligomer (product name: SP-018) obtained in Example 8 were, respectively, added to 120 g of the aqueous solution of ethyleneimine oligomer (product name: SP-003) obtained in Example 7. Next, 100 g of a 10 wt % polyvinyl acetal aqueous solution used as a plasticizer and 60 g of pure water were added to these solutions, respectively, followed by mixing under agitation at room temperature for 6 hours. As a result, three types of mixed solutions having concentrations of the ethyleneimine oligomer (product name: SP-018, with an average molecular weight of 1,800), relative to the ethyleneimine oligomer (product name: SP-003, with an average molecular weight of 300), of about 25 wt %, 50 wt % and 75 wt % were obtained.

### Example 15

The aqueous solutions of the allylamine oligomers (product names: PAA-01, PAA-03, PAA-05) obtained in Examples 10 to 12 were, respectively, added to 120 g of the aqueous solution of the ethyleneimine oligomer (product name: SP-003) obtained in Example 7 in an amount of 60 g to prepare three types of solutions. Next, 100 g of a 10 wt % polyvinyl acetal aqueous solution used as a plasticizer and 60 g of pure water were added to these solutions, respectively, followed by agitation at room temperature for 6 hours to obtain three types of mixed solutions.

### Example 16

100 g of the aqueous solution of the ethyleneimine oligomer (product name: SP-003) obtained in Example 7, 200 g of the aqueous solution of the ethyleneimine oligomer (product name: SP-200) obtained in Example 9, and 110 g of pure water were agitated at room temperature for 6 hours to obtain a mixed solution.

### Example 17

90 g of polyethyleneimine (product name: P-1000, an average molecular weight of 70,000), made by Nippon Shokubai Co., Ltd., was placed in a one liter measuring flask, to which 600 g of pure water was added. The mixture was mixed under agitation at room temperature for 6 hours to obtain an 13 wt % aqueous solution of polyethyleneimine.

### Example 18

A solution was prepared wherein 120 g of the aqueous solution of the ethyleneimine oligomer (product name: SP-018) obtained in Example 8 was added to 120 g of the aqueous solution of the ethyleneimine oligomer (product name: SP-003) obtained in Example 7. Next, 100 g of a 10 wt % polyvinyl acetal aqueous solution used as a plasticizer and 65 g of pure water were further added to the prepared solution, followed by mixing under agitation at room temperature of 6 hours. As a result, the mixed solution obtained had a concentration of the ethyleneimine oligomer (product name: SP-018, with an average molecular weight of 1,800), relative to the ethyleneimine oligomer (product name: SP-003, with an average molecular weight of 300), of 100 wt %.

### Example 19

A solution was prepared wherein 120 g of the aqueous solution of the ethyleneimine oligomer (product name: SP-200) obtained in Example 9 was added to 120 g of the aqueous solution of the ethyleneimine oligomer (product name: SP-003) obtained in Example 7. Next, 100 g of a 10 wt % polyvinyl acetal aqueous solution used as a plasticizer and 65 g of pure water were further added to the prepared solution, followed by mixing under agitation at room temperature of 6 hours. As a result, the mixed solution obtained had a concentration of the ethyleneimine oligomer (product name: SP-200, with an average molecular weight of 10,000), relative to the ethyleneimine oligomer (product name: SP-003, with an average molecular weight of 300), of 100 wt %.

### Example 20

A solution was prepared wherein 180 g of the aqueous solution of the polyethyleneimine (product name: P-1000, with an average molecular weight of 70,000, 30 wt % resin concentration), made by Nippon Shokubai Co., Ltd., was added to 60 g of the aqueous solution of the ethyleneimine oligomer (product name: SP-003) obtained in Example 7. Next, 50 g of a 10 wt % polyvinyl acetal aqueous solution used as a plasticizer and 60 g of pure water were further added to the prepared solution, followed by mixing under agitation at room temperature of 6 hours. As a result, the mixed solution obtained had a concentration of the polyethyleneimine (product name: P-1000, with an average molecular weight of 70,000), relative to the ethyleneimine oligomer (product name: SP-003, with an average molecular weight of 300), of 100 wt %.

### Formation of a Micropattern

### Example 21

Five types of micropattern forming materials obtained in Example 13 were, respectively, dropped over silicon wafers on which the resist pattern obtained in Example 5 was formed, and spin coated by use of a spinner. Thereafter, a hot plate was used for pre-baking the respective samples at 85° C. for 70 seconds, thereby forming five micropattern forming films.

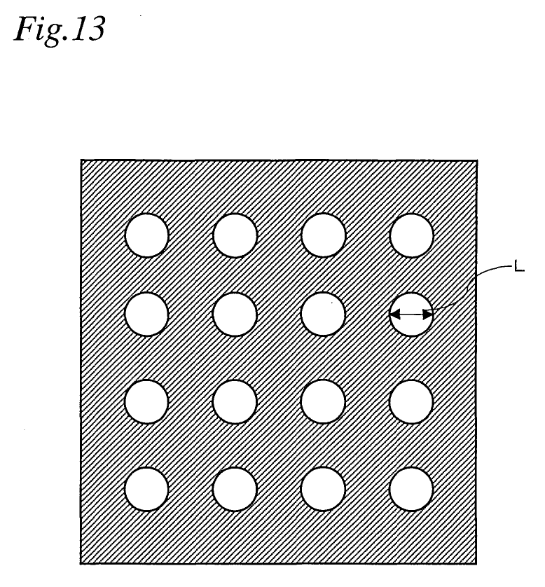

Next, the micropattern forming films were; respectively, subjected to MB treatment at 120° C. for 90 seconds by use of a hot plate, so that crosslinking reaction was allowed to proceed in the respective micropattern forming films, thereby forming insolubilized layers therein. Thereafter, developing treatment with pure water was carried out to remove a non-insolubilized layer of the micropattern forming film where no crosslinking reaction took place. Subsequently, a hot plate was used for post-baking the films at 90° C. for 90 seconds, thereby forming five micropatterns each on the resist pattern as shown in. FIG. 13. It will be noted that the shaded portion means a portion where a micropattern is formed.

In Table 1, the relation between the concentration of ethyleneimine oligomer and the hole diameter L of a micropattern is shown. In Table 1, the difference between the hole diameter of the resist pattern and the hole diameter of the micropattern indicates a thickness of an insolubilized layer formed on the resist pattern.

TABLE 1

| | |
|---|---|
| Concentration of | |
| Ethyleneimine | Hole Diameter (nm) |

| Oligomer (wt %) | Resist Pattern | Micropattern |
|---|---|---|
| 4 | 108 | 102 |
| 16 | 108 | 100 |
| 50 | 108 | 97 |
| 100 | 108 | 85 |
| 200 | 167 | 56 |

As shown in Table 1, when the concentration of the ethyleneimine oligomer relative to the plasticizer was changed, the hole diameter of the micropattern also changed. More particularly, a higher concentration of the ethyleneimine oligomer relative to the plasticizer resulted in a smaller hole diameter of the micropattern, with an increasing thickness of the insolubilized layer. Accordingly, it will be understood that when the mixing amount of the ethyleneimine oligomer based on the plasticizer is changed, the thickness of the insolubilized layer to be formed on the resist pattern can be controlled.

### Example 22

The micropattern forming material obtained in Example 13 and having a concentration of the ethyleneimine oligomer of about 100 wt % was dropped over the silicon wafer obtained in Example 5 and formed thereon with the resist pattern and spin coated by use of a spinner. Thereafter, a hot plate was used for pre-baking at 85° C. for 70 seconds to form a micropattern forming film.

Next, the wafer was exposed to light over the entire surface thereof by use of a KrF excimer reduced projection aligner. Thereafter, a hot plate was used for MB treatment at 150° C. for 90 seconds, so that crosslinking reaction was caused to proceed in the micropattern forming film thereby forming an insolubilized layer.

Next, pure water was used for developing treatment to remove a non-insolubilized layer of the micropattern forming film where no crosslinking reaction took place. Subsequently, a hot plate was used for post-baking at 110° C. for 90 seconds to obtain a micropattern formed on the resist pattern as shown in FIG. 13.

Table 2 shows the results of the comparison between the hole diameter of the micropattern of this example and the hole diameter of the case where whole exposure was not performed prior to MB treatment. In Table 2, the difference between the hole diameter of the resist pattern and the hole diameter of the micropattern indicates the thickness of the insolubilized layer to be formed on the resist pattern.

TABLE 2

| | Hole Diameter |
|---|---|
| Sample | (nm) |
| Resist Pattern | 118 |
| Micropattern | 87 |
| (not exposed) | |
| Micropattern | 79 |
| (exposed/Example 22) | |

As shown in Table 2, the hole diameter in case where no exposure was performed prior to the MB treatment was reduced by about 30 nm over the hole diameter of the resist pattern prior to the formation of the insolubilized layer. On the other hand, where exposure was performed prior to the MB treatment, the hole diameter was reduced by about 40 nm. More particularly, when exposure was performed, the insolubilized layer formed on the resist pattern became greater in thickness.

### Example 23

Three types of micropattern forming materials obtained in Example 14 were, respectively, dropped over the silicon wafers obtained in Example 5 and formed with the resist pattern thereon and spin coated by use of a spinner. Thereafter, a hot plate was used for pre-baking the respective samples at 85° C. for 70 seconds, thereby forming three types of micropattern forming films.

Next, the micropattern forming films were, respectively, subjected to MB treatment at 120° C. for 90 seconds by use of a hot plate, so that crosslinking reaction was allowed to proceed in the respective micropattern forming films, thereby forming insolubilized layers therein. Thereafter, developing treatment with pure water was carried out to remove a non-insolubilized layer of the micropattern forming film where no crosslinking reaction took place. Subsequently, a hot plate was used for post-baking the films at 90° C. for 90 seconds, thereby forming three micropatterns each on the resist pattern as shown in FIG. 13.

In Table 3, the relation between the concentration of the ethyleneimine oligomer (product name: SP-018) and the hole diameter L of the micropattern is shown. For comparison, the hole diameter at an SP-018 concentration of 0 (zero) is also shown. In Table 3, the difference between the hole diameter of the resist pattern and the hole diameter of the micropattern indicates a thickness of the insolubilized layer formed on the resist pattern.

TABLE 3

| | |
|---|---|
| Concentration of | Hole diameter (nm) |

| SP-018 (wt %) | Resist Pattern | Micropattern |
|---|---|---|
| 0 | 108 | 85 |
| 25 | 108 | 82 |
| 50 | 108 | 74 |
| 100 | 108 | 65 |

As shown in Table 3, the change in concentration of the ethyleneimine oligomer (product name: SP-018, with an average molecular weight of 1,800) relative to the ethyleneimine oligomer (product name: SP-003, with an average molecular weight of 300) resulted in the change in hole diameter of the micropattern. More particularly, a higher concentration of the ethyleneimine oligomer having a greater average molecular weight lead to a smaller hole diameter of the resultant micropattern, with an increasing thickness of the insolubilized layer. Accordingly, it will be understood that when ethyleneimine oligomers that are similar in structure but have different average molecular weights are mixed at different mixing ratio; the thickness of the insolubilized layer to be formed on the resist pattern can be controlled as desired.

### Example 24

The micropattern forming material obtained in Example 13 and having an ethylene oligomer concentration of about 200 wt % was dropped over the silicon wafer obtained in Example 5 and formed with the resist pattern thereon and spin coated by use of a spinner. Thereafter, a hot plate was used for pre-baking at 85° C. for 70 seconds to form a micropattern forming film.

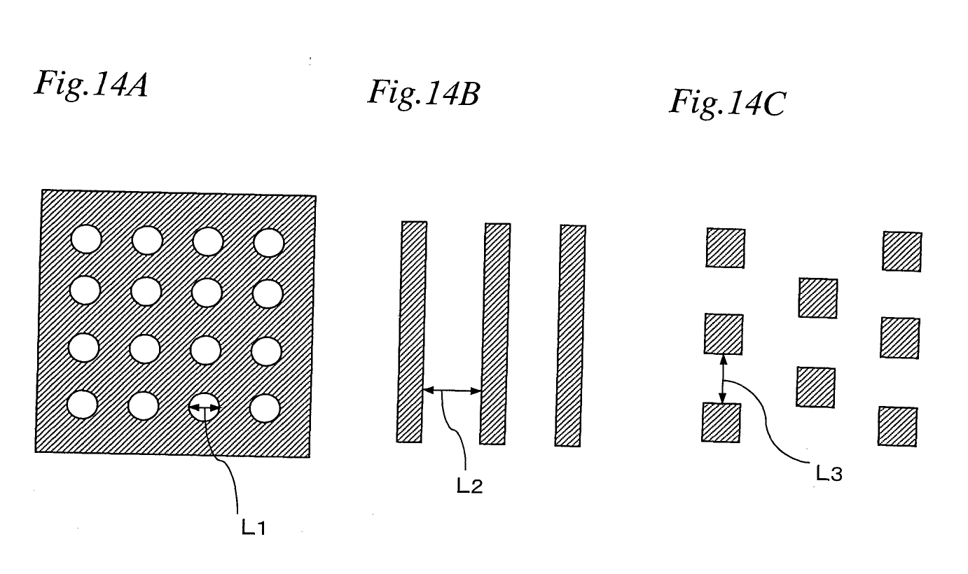

Next, MB treatment was carried out by use of a hot plate so that crosslinking reaction was caused to proceed in the micropattern forming film thereby forming an insolubilized layer. To this end, three different MB treating conditions of 100° C. and 90 seconds, 110° C. and 90 seconds, and 120° C. and 90 seconds were used to provide samples. Thereafter, pure water was used for development to remove a non-insolubilized layer of each micropattern forming film where no crosslinking reaction took place. Subsequently, a hot plate was used for post-baking at 90° C. for 90 seconds, thereby forming three types of micropatterns each on the resist pattern as is particularly shown in FIGS. 14A to 14C. It will be noted that the shaded portion in the figures indicates a portion where the micropattern is formed.

The hole diameter L₁ and line width L₂ of the micropattern and the space width L₃ of the island pattern, all shown in FIGS. 14A to 14C, were measured, from which the variation in thickness of the insolubilized layer depending on the MB treating conditions was checked. The results are shown in Table 4. In Table 4, the difference between the hole diameter of the resist pattern and each of the hole diameter L₁ and line width L₂ of the micropattern (specifically, space width L₂ of the line micropattern) and the space width L₃ in the island pattern indicates a thickness of the insolubilized layer formed on the resist pattern.

TABLE 4

| | Structure Dimension (nm) | | | | | |
|---|---|---|---|---|---|---|
| MB Treating | Resist Pattern | | | Micropattern | | |
| Conditions | L₁ | L₂ | L₃ | L₁ | L₂ | L₃ |
| 100° C./90 seconds | 167 | 175 | 175 | 87 | 104 | 93 |
| 110° C./90 seconds | 167 | 175 | 175 | 71 | 88 | 80 |
| 120° C./90 seconds | 167 | 175 | 175 | 56 | 72 | 60 |

As shown in Table 4, when the MB treating temperature was changed, the hole diameter L₁ and line width L₂ of the micropattern and the space width L₃ also changed. More particularly, a higher MB treating temperature resulted in a greater thickness of the insolubilized layer. Thus, it will be understood that the thickness of the insolubilized layer to be formed on the resist pattern can be controlled by changing the MB treating temperature.

### Example 25

The three types of micropattern forming materials obtained in Example 15 were, respectively, dropped over the silicon wafers obtained in Example 5 and formed with the resist patter thereon and spin coated by use of a spinner. Thereafter, a hot plate was used for pre-baking the respective samples at 85° C. for 70 seconds, thereby obtaining three types of micropattern forming films.

Next, the films were, respectively, subjected to MB treatment by use of a hot plate at 120° C. for 90 seconds, so that crosslinking reaction was caused to proceed in the respective micropattern forming films to form an insolubilized layer therein. Thereafter, pure water was used for development so that a non-insolubilized layer of each micropattern forming film where no crosslinking reaction took place was removed. Subsequently, a hot plate was used for post-baking at 90° C. for 90 seconds to form three types of micropatterns on the resist patterns as shown in FIGS. 14A to 14C.

The hole diameter L₁ of the micropattern shown in FIG. 14(a) was measured to check the variation in thickness of the insolubilized layer depending on the type of allylamine oligomer. The results are shown in Table 5. For comparison, the hole diameter for a micropattern forming material (using ethyleneimine oligomer SP-003 alone) to which no allylamine oligomer is added is also shown. In Table 5, the difference between the hole diameter of the resist pattern and the hole diameter of the micropattern indicates a thickness of the insolubilized layer formed on the resist pattern.

TABLE 5

| | |
|---|---|
| Allylamine Oligomer | Hole Diameter (nm) |

| (product name) | Resist Pattern | Micropattern |
|---|---|---|
| nil | 108 | 85 |
| PAA-01 | 108 | 79 |
| PAA-03 | 108 | 70 |
| PAA-05 | 108 | 58 |

As shown in Table 5, when the type of allylamine oligomer was changed, the hole diameter of the micropattern changed. Accordingly, it will be understood that even if allylamine oligomers are, respectively, added to an ethyleneimine oligomer in an equal amount, the thickness of the insolubilized layer to be formed on the resist pattern can be controlled by changing the type of allylamine oligomer and the average molecular weight.

### Example 26

Five types of micropattern forming materials obtained in Example 13 were, respectively, dropped over the silicon wafers obtained in Example 4 and formed with the resist pattern thereon and spin coated by use of a spinner. Thereafter, the respective samples were subjected to pre-baking at 85° C. for 70 seconds by use of a hot plate, thereby forming five types of micropattern forming films.

Next, a hot plate was used for MB treatment at 100° C. for 90 seconds so that crosslinking reaction was caused to proceed in the respective micropattern forming films thereby forming an insolubilized layer therein. Thereafter, pure water was used for development so that a non-insolubilized layer of each micropattern forming film where no crosslinking reaction took place was removed. Subsequently, a hot plate was used for post-baking at 90° C. for 90 seconds to form three types of micropatterns on the resist patterns as shown in FIG. 13.

In Table 6, the relation between the concentration of the ethyleneimine oligomer and the hole diameter L of the micropattern is shown. In Table 6, the difference between the hole diameter of the resist pattern and the hole diameter of the micropattern indicates the thickness of the insolubilized layer formed on the resist pattern.

TABLE 6

| | |
|---|---|
| Concentration of | |
| Ethyleneimine | Hole Diameter (nm) |

| Oligomer (wt %) | Resist Pattern | Micropattern |
|---|---|---|
| 4 | 172 | 165 |
| 16 | 172 | 154 |
| 50 | 172 | 121 |
| 100 | 172 | 110 |
| 200 | 172 | 77 |

As shown in Table 6, the change in concentration of the ethyleneimine oligomer relative to the plasticizer lead to a change in hole diameter of the micropattern. More particularly, a higher concentration of the ethyleneimine oligomer based on the plasticizer resulted in a smaller hole diameter of the micropattern, with an increasing thickness of the insolubilized layer. Thus, it will be understood that the thickness of the insolubilized layer to be formed on the resist pattern can be controlled by changing a mixing ratio of the ethyleneimine oligomer to the plasticizer.

### Example 27

The micropattern forming material obtained in Example 13 and having an ethylene oligomer concentration of about 100 wt % was dropped over the silicon wafer obtained in Example 4 and formed with the resist pattern thereon, and spin coated by use of a spinner. Thereafter, a hot plate was used for pre-baking at 85° C. for 70 seconds to form a micropattern forming film.

Next, MB treatment was carried out by use of a hot plate so that crosslinking reaction was caused to proceed in the micropattern forming film thereby forming an insolubilized layer. To this end, three different MB treating conditions of 100° C. and 90 seconds, 110° C. and 90 seconds, and 120° C. and 90 seconds were used to provide samples. Thereafter, pure water was used for development to remove a non-insolubilized layer of each micropattern forming film where no crosslinking reaction took place. Subsequently, a hot plate was used for post-baking at 90° C. for 90 seconds, thereby forming three types of micropatterns each on the resist pattern as is particularly shown in FIGS. 14A to 14C.

The hole diameter L₁ and line width L₂ of the micropattern and the space width L₃ of the island pattern, all shown in FIGS. 14A to 14C, were measured, from which the variation in thickness of the insolubilized layer depending on the MB treating conditions was checked. The results are shown in Table 7. In Table 7, the difference between the hole diameter of the resist pattern and each of the hole diameter L₁ and line width L₂ of the micropattern (specifically, space width L₂ of the line micropattern) and the space width L₃ in the island pattern indicates a thickness of the insolubilized layer formed on the resist pattern.

TABLE 7

| | Structure Dimension (nm) | | | | | |
|---|---|---|---|---|---|---|
| MB Treating | Resist Pattern | | | Micropattern | | |
| Conditions | L₁ | L₂ | L₃ | L₁ | L₂ | L₃ |
| 100° C./90 seconds | 175 | 182 | 180 | 110 | 115 | 114 |
| 110° C./90 seconds | 175 | 182 | 180 | 106 | 110 | 110 |
| 120° C./90 seconds | 175 | 182 | 180 | 101 | 104 | 101 |

As shown in Table 7, when the MB treating temperature was changed, the hole diameter L₁ and line width L₂ of the micropattern and the space width L₃ also changed. More particularly, a higher MB treating temperature resulted in a greater thickness of the insolubilized layer. Thus, it will be understood that the thickness of the insolubilized layer to be formed on the resist pattern can be controlled by changing the MB treating temperature.

### Example 28

The micropattern forming material obtained in Example 13 and having an ethylene oligomer concentration of about 100 wt % was dropped over the silicon wafer obtained in Example 2 and formed with the resist pattern thereon, and spin coated by use of a spinner. Likewise, a sample was made by dropping and spin coating the micropattern forming material having an ethylene oligomer concentration of about 200 wt %. Thereafter, a hot plate was used for pre-baking the respective samples at 85° C. for 70 seconds to form two types of samples having different micropattern forming films.

Next, MB treatment was carried out by use of a hot plate so that crosslinking reaction was caused to proceed in the micropattern forming film thereby forming an insolubilized layer. To this end, two different MB treating conditions of 100° C. and 90 seconds and 120° C. and 90 seconds were used to provide samples. Thereafter, pure water was used for development to remove a non-insolubilized layer of the micropattern forming film where no crosslinking reaction took place. Subsequently, a hot plate was used for post-baking at 90° C. for 90 seconds, thereby forming four types of micropatterns each on the resist pattern as shown in FIG. 13.

In Table 8, the relation between the concentration of the ethyleneimine oligomer and the hole diameter L of the micropattern is shown. In Table 8, the difference between the hole diameter of the resist pattern and the hole diameter of the micropattern indicates a thickness of the insolubilized layer formed on the resist pattern.

TABLE 8

| Concentration of | | Hole Diameter (nm) | |
|---|---|---|---|
| Ethyleneimine | MB treating | Resist | |
| Oligomer (wt %) | Conditions | Pattern | Micropattern |
| 100 | 100° C./90 seconds | 220 | 192 |
| 100 | 120° C./90 seconds | 220 | 177 |
| 200 | 100° C./90 seconds | 220 | 170 |
| 200 | 120° C./90 seconds | 220 | 157 |

As shown in Table 8, when the concentration of the ethyleneimine oligomer relative to the plasticizer was changed, the hole diameter of the micropattern changed. Likewise, when the MB treating temperature became high, the hole diameter of the micropattern also changed. Thus, it will be understood that because such a change as in Example 21 and Example 24 is shown, the thickness of the insolubilized layer to be formed on the resist pattern can be controlled by changing the mixing ratio of the ethyleneimine oligomer and the MB treating temperature even if the type of resist composition is changed.

### Example 29

The micropattern forming material obtained in Example 13 and having an ethyleneimine oligomer concentration of about 100 wt % was dropped over the silicon wafer obtained in Example 3 and formed with the resist pattern thereon and spin coated by use of a spinner. Likewise, a sample was also made by dropping and spin coating the micropattern forming material having an ethyleneimine oligomer concentration of about 200 wt %. Thereafter, a hot plate was used for pre-baking the respective samples at 85° C. for 70 seconds to form two types of samples having different micropattern forming films.

Next, MB treatment was carried out by use of a hot plate so that crosslinking reaction was caused to proceed in the micropattern forming film thereby forming an insolubilized layer. To this end, two different MB treating conditions of 100° C. and 90 seconds and 120° C. and 90 seconds were used to provide samples. Thereafter, pure water was used for development to remove a non-insolubilized layer of the micropattern forming film where no crosslinking reaction took place. Subsequently, a hot plate was used for post-baking at 90° C. for 90 seconds, thereby forming four types of micropatterns each on the resist pattern as shown in FIG. 13.

In Table 9, the relation between the concentration of the ethyleneimine oligomer and the hole diameter L of the micropattern is shown. In Table 9, the difference between the hole diameter of the resist pattern and the hole diameter of the micropattern indicates a thickness of the insolubilized layer formed on the resist pattern.

TABLE 9

| Concentration of | | Hole Diameter (nm) | |
|---|---|---|---|
| Ethyleneimine | MB treating | Resist | |
| Oligomer (wt %) | Conditions | Pattern | Micropattern |
| 100 | 100° C./90 seconds | 220 | 205 |
| 100 | 120° C./90 seconds | 220 | 194 |
| 200 | 100° C./90 seconds | 220 | 188 |
| 200 | 120° C./90 seconds | 220 | 175 |

As shown in Table 9, when the concentration of the ethyleneimine oligomer relative to the plasticizer was changed, the hole diameter of the micropattern changed. Likewise, when the MB treating temperature became high, the hole diameter of the micropattern also changed. Thus, it will be understood that because such a change as in Example 21 and Example 24 is shown, the thickness of the insolubilized layer to be formed on the resist pattern can be controlled by changing the mixing ratio of the ethyleneimine oligomer and the MB treating temperature even if the type of resist composition is changed.

### Example 30

The micropattern forming material obtained in Example 13 and having an ethyleneimine oligomer concentration of about 100 wt % was dropped over the silicon wafer obtained in Example 6 and formed with the resist pattern thereon and spin coated by use of a spinner. Likewise, a sample was also made by dropping and spin coating the micropattern forming material having an ethyleneimine oligomer concentration of about 200 wt %. Thereafter, a hot plate was used for pre-baking the respective samples at 85° C. for 70 seconds to form two types of samples having different micropattern forming films.

Next, MB treatment was carried out by use of a hot plate so that crosslinking reaction was caused to proceed in the micropattern forming film thereby forming an insolubilized layer. To this end, two different MB treating conditions of 100° C. and 90 seconds and 120° C. and 90 seconds were used to provide samples. Thereafter, pure water was used for development to remove a non-insolubilized layer of the micropattern forming film where no crosslinking reaction took place. Subsequently, a hot plate was used for post-baking at 90° C. for 90 seconds, thereby forming four types of micropatterns each on the resist pattern as shown in FIG. 13.

In Table 10, the relation between the concentration of the ethyleneimine oligomer and the hole diameter L of the micropattern is shown. In Table 10, the difference between the hole diameter of the resist pattern and the hole diameter of the micropattern indicates a thickness of the insolubilized layer formed on the resist pattern.

TABLE 10

| Concentration of | | Hole Diameter (nm) | |
|---|---|---|---|
| Ethyleneimine | MB treating | Resist | |
| Oligomer (wt %) | Conditions | Pattern | Micropattern |
| 100 | 100° C./90 seconds | 120 | 100 |
| 100 | 120° C./90 seconds | 120 | 86 |
| 200 | 100° C./90 seconds | 120 | 78 |
| 200 | 120° C./90 seconds | 120 | 63 |

As shown in Table 10, when the concentration of the ethyleneimine oligomer relative to the plasticizer was changed, the hole diameter of the micropattern changed. Likewise, when the MB treating temperature became high, the hole diameter of the micropattern also changed. Thus, it will be understood that because such a change as in Example 21 and Example 24 is shown, the thickness of the insolubilized layer to be formed on the resist pattern can be controlled by changing the mixing ratio of the ethyleneimine oligomer and the MB treating temperature even if the type of resist composition is changed.

### Example 31

An electron beam was selectively irradiated through an electron beam-shielding plate on the silicon wafer obtained in Example 5 and formed with the resist pattern thereon. The dosage was at 50 μC/cm². Next, the micropattern forming material obtained in Example 13 and having an ethyleneimine oligomer concentration of about 100 wt % was dropped over the wafer and spin coated by use of a spinner. Thereafter, a hot plate was used for pre-baking at 85° C. for 70 seconds to form a micropattern forming film.

Next, a hot plate was used for MB treatment at 120° C. for 90 seconds, so that crosslinking reaction was caused to proceed in the micropattern forming film thereby forming an insolubilized layer.

Next, development was carried out by use of pure water to remove a non-insolubilized layer of the micropattern forming film where no crosslinking reaction took place. Subsequently, a hot plate was used for post-baking at 110° C. for 70 seconds to form a micropattern on the resist pattern as shown in FIG. 13.

In Table 11, the results of comparison between the hole diameter at a portion irradiated with the electron beam and the hole diameter at a portion not irradiated with the electron beam are shown. In Table 11, the difference between the hole diameter of the resist pattern and the hole diameter of the micropattern indicates a thickness of the insolubilized layer formed on the resist pattern.

TABLE 11

| Sample | Hole Diameter (nm) |
|---|---|
| Resist Pattern | 175 |
| Micropattern | 175 |
| (at a portion irradiated with | |
| an electron beam) | |
| Micropattern (at a portion | 101 |
| not irradiated with an | |
| electron beam) | |

As shown in Table 11, the hole diameter at the portion which was not irradiated with the electron beam was reduced in comparison with the hole diameter of the resist pattern prior to the formation of the insolubilized layer. On the other hand, little change was observed with respect to the hole diameters at the portion which was irradiated with the electron beam. Thus, it will be understood that the insolubilzied layer can be formed selectively on the resist pattern by selective irradiation of the electron beam.

### Example 32

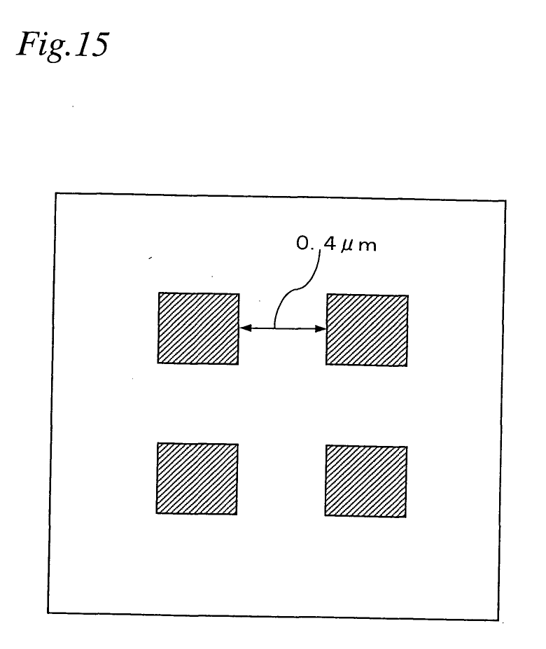

As shown in FIG. 15, a resist pattern was formed on a silicon wafer, on which an oxide film was formed, in the same manner as in example 5. It will be noted that the shaded portion indicates a portion where the resist is formed. Next, the micropattern forming material obtained in Example 13 and having an ethyleneimine oligomer concentration of about 100 wt % was dropped and spin coated by use of a spinner. Likewise, the micropattern forming material having an ethyleneimine oligomer concentration of about 200 wt % was dropped and spin coated by use of a spinner to obtain a sample. Thereafter, a hot plate was used for pre-baking the respective samples at 85° C. for 70 seconds thereby providing two types of samples having different types of micropattern forming films.

Next, a hot plate was used for MB treatment at 105° C. for 90 seconds, so that crosslinking reaction was caused to proceed in the micropattern forming film thereby forming an insolubilized layer. Next, development was carried out by use of pure water to remove a non-insolubilized layer of the micropattern forming film where no crosslinking reaction took place. Subsequently, a hot plate was used for post-baking at 90° C. for 90 seconds to obtain two types of samples wherein a micropattern was formed on the resist film.

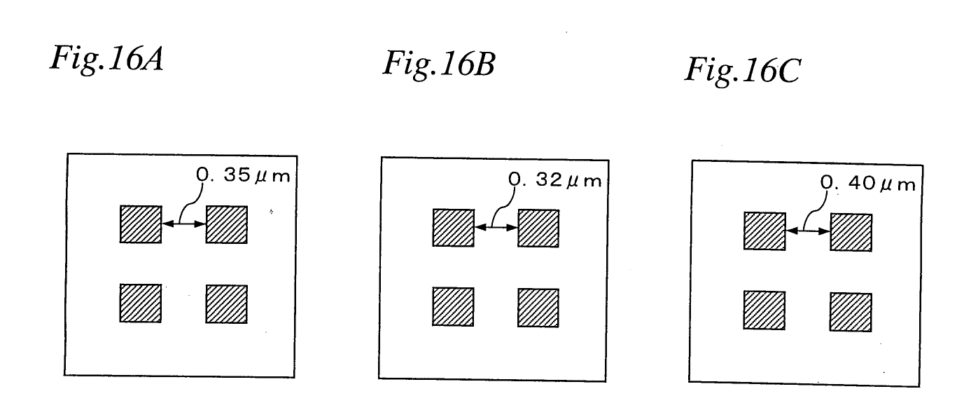

Subsequently, the underlying oxide film was etched by use of an etching device, and the form of the pattern of the oxide film after the etching was observed. The results are shown in Table 12 and FIGS. 16A and 16B. The portion to be measured is a space width in the island pattern as shown. For comparison, the results of etching of a sample having a resist pattern alone are also shown (FIG. 16C). It will be noted that the shaded portion means a portion wherein the resist is formed.

TABLE 12

| | |
|---|---|
| Concentration of | Space Width(μm) |

| Ethyleneimine | Resist | |
|---|---|---|
| Oligomer (wt %) | Pattern | Micropattern |
| 100 | 0.40 | 0.35 |
| 200 | 0.40 | 0.32 |

With respect to the samples shown in FIG. 16A and FIG. 16B, the oxide film after etching was observed. In both cases, an oxide pattern having good patterning properties was formed. On the other hand, with the sample shown in FIG. 16C, the linearity of the resist pattern was not good, which is reflected on the oxide film pattern whose linearity was not good.

### Example 33

Three types of micropattern forming materials obtained in Examples 18, 19 and 20 were, respectively, dropped over the silicon wafers obtained in Example 5 and formed with the resist pattern thereon and spin coated by use of a spinner. Thereafter, a hot plate was used for pre-baking the respective samples at 85° C. for 70 seconds, thereby forming three types of micropattern forming films.

Next, a hot plate was used for MB treatment at 120° C. for 90 seconds, so that crosslinking reaction was caused to proceed in the micropattern forming film thereby forming an insolubilized layer. Thereafter, pure water was used for development so as to remove a non-insolubilized layer of the micropattern forming film where no crosslinking reaction took place. Subsequently, a hot plate was used for post-baking at 90° C. for 90 seconds to form three types of micropatterns each on the resist pattern as shown in FIG. 13.

In Table 13, the relation between the average molecular weight of the water-soluble component added to an ethyleneimine oligomer having an average molecular weight of 300 and the hole diameter L of the micropattern, is shown. In Table 13, the difference between the hole diameter of the resist pattern and the hole diameter of the micropattern indicates a thickness of the insolubilized layer formed on the resist pattern.

TABLE 13

Hole Diameter (nm)

| Water-soluble Component | Resist | Micro- |
|---|---|---|
| (Molecular Weight) | Pattern | pattern |
| Ethyleneimine Oligomer | 174 | 76 |
| (1,800) | | |
| Ethyleneimine Oligomer | 174 | 68 |
| (10,000) | | |
| Polyethyleneimine | 174 | Not formed |
| (70,000) | | (Pattern |
| | | Buried) |

As shown in Table 13, where ethyleneimine oligomers having an average molecular weight of 1,800 and an average molecular weight of 10,000 were, respectively, added to the silicon wafer, a good micropattern was formed. In this connection, a thicker insolubilized layer was formed when adding the ethyleneimine oligomer having an average molecular weight of 10,000. On the other hand, when polyethyleneimine having an average molecular weight of 70,000 was added, it was not possible to form a desired micropattern.

The features and advantages of the present invention may be summarized as follows.

According to one aspect, because a micropattern forming film was insolubilized at a portion where a resist pattern and the micropattern forming film are in contact with each other and a non-insolubilized micropattern forming film is subsequently removed, a fine pattern can be formed beyond the limit of an exposure wavelength.

According to another aspect, because a micropattern forming material comprising a water-soluble component, water and/or an organic solvent miscible with water is used, an underlying resist pattern is not dissolved.

According to other aspect, a good micropattern can be formed on an acrylic resist. Moreover, defects such as bridging can be reduced in number, and thus a good micropattern can be formed on a resist pattern.

According to further aspect, when an underlying semiconductor base material is etched using the micropattern according to the invention as a mask, a semiconductor base material pattern of good patterning properties can be obtained.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-253923, filed on Aug. 30, 2002 including specification, claims, drawings and summary, on which the Convention priority of the present application is based, are incorporated herein by reference in its entirety.

What is claimed is:

1. A micropattern forming material comprising;
a water-soluble component which is crosslinkable in the presence of an acid, and
water and/or an organic solvent miscible with water:
coating on a resist pattern capable of supplying an acid:
wherein said water-soluble component consists of at least one selected from the group comprising water-soluble monomers, water-soluble oligomers, copolymers of water-soluble monomers and salts thereof, having a functional group reactable with a carboxyl group, is crosslinked by the action of said acid from said resist pattern at a portion in contact with said resist pattern to form a water or alkali-insoluble film.

2. The micropattern forming material according to claim 1, wherein said water-soluble oligomer is the oligomer polymerized said water-soluble monomer in number of 2 to 240, or the oligomer having an average molecular weight of 10,000 or below.

3. The micropattern forming material according to claim 1, wherein said water-soluble monomer is at least one selected from the group comprising a sulfonate-containing monomer, a carboxyl group-containing monomer, a hydroxyl group-containing monomer, an amido group-containing monomer, an amino group-containing monomer, a diallylglycinonitrile group-containing monomer, an ether group-containing monomer, a pyrrolidone derivative and an ethyleneimine derivative.

4. The micropattern forming material according to claim 2, wherein said water-soluble oligomer consists of an ethyleneimine oligomer having an average molecular weight of 250 to 10,000.

5. The micropattern forming material according to claim 1, further comprising a plasticizer and/or a surface active agent.

6. A method for forming a fine structure, comprising:
a first step of forming a resist pattern capable of supplying an acid on a support or a thin film formed on a support;
a second step of coating a micropattern forming material onto said resist pattern to form a micropattern forming film;
a third step of supplying said acid from said resist pattern to cause a crosslinking reaction at a portion of said micropattern forming film contacting with said resist pattern to form a water or alkali-insoluble film; and
a forth step of removing a water or alkali-soluble portion of said micropattern forming film:
wherein said micropattern forming material comprises;
a water-soluble component consisting of at least one selected from the group comprising water-soluble monomers, water-soluble oligomers, copolymers of water-soluble monomers and salts thereof, having a functional group reactable with a carboxyl group, and water and/or an organic solvent miscible with water.

7. The method according to claim 6, wherein said third step is a thermal treating step and/or an exposure step.

8. The method according to claim 6, wherein a thickness of said water or alkali-insoluble film is controlled by controlling a concentration of said water-soluble component in said micropattern forming material.

9. The method according to claim 6, wherein a thickness of said water or alkali-insoluble film is controlled by controlling a mixing ratio of components having different average molecular weights included in said water-soluble component.

10. The method according to claim 9, wherein said water-soluble component consists of an ethyleneimine oligomer.

11. The method according to claim 6, wherein a thickness of said water or alkali-insoluble film is controlled by controlling a mixing ratio of components of a different kind included in said water-soluble component.

12. The method according to claim 11, wherein said water-soluble component consists of an allylamine oligomer and an ethyleneimine oligomer.

13. The method according to claim 7, wherein a thickness of said water or alkali-insoluble film is controlled by controlling the temperature in said thermal treating step.

14. The method according to claim 6, wherein said resist pattern is formed of a resist capable of generating an acid by thermal treatment.

15. The method according to claim 6, wherein said resist pattern is formed of a resist capable of generating an acid by exposure to light.

16. The method according to claim 6, wherein said resist pattern is formed of a resist containing an acid.

17. The method according to claim 6, wherein said resist pattern formed in said first step is surface-treated with an acidic liquid or an acidic gas, followed by said second step.

18. The method according to claim 6, wherein light is exposed to a given region of said micropattern forming film formed in said second step, followed by said third step.

19. The method according to claim 6, wherein an electron beam is irradiated to a given region of said micropattern forming film formed in said second step, followed by said third step.
